(19) United States
(12) Patent Application Publication
(10) Pub. No.: US 2025/0255063 A1
(43) Pub. Date: Aug. 7, 2025

(54) DISPLAY MODULE AND VEHICLE TERMINAL

(71) Applicant: Shanghai Tianma Micro-electronics Co., Ltd., Shanghai (CN)

(72) Inventors: Donghua CHEN, Shanghai (CN); Yuan DING, Shanghai (CN)

(21) Appl. No.: 18/663,947

(22) Filed: May 14, 2024

(30) Foreign Application Priority Data
Feb. 7, 2024 (CN) 202410173989.X

(51) Int. Cl. H01L 33/64; H01L 25/075

(52) U.S. Cl. CPC H10H 20/8582; H01L 25/0753; H10H 20/8586

(57) ABSTRACT

The present disclosure provides a display module and a vehicle terminal. The display module includes a display panel and a heat-dissipation part. The heat-dissipation part at least includes a main-heat-dissipation portion and a sub-heat-dissipation portion; and along a direction perpendicular to a plane of the display panel, the main-heat-dissipation portion is at least partially overlapped with the display panel; along a direction in parallel with the plane of the display panel, the sub-heat-dissipation portion is at least on a side of the main-heat-dissipation portion; and the sub-heat-dissipation portion includes a blade structure; and the main-heat-dissipation portion is connected to the blade structure of the sub-heat-dissipation portion.

### CROSS-REFERENCE TO RELATED APPLICATION

The present disclosure claims the priority of Chinese Patent Application No. 202410173989.X, filed on Feb. 7, 2024, the content of which is incorporated herein by reference in its entirety.

### TECHNICAL FIELD

The present disclosure generally relates to the field of display technology and, more particularly, relates to a display module and a vehicle terminal.

### BACKGROUND

Existing displays include passive light-emitting displays and active light-emitting displays. Passive light-emitting displays are display devices that require backlight use for display. Common examples of passive light-emitting displays include liquid crystal displays (LCDs). Active light-emitting devices are display devices that may be excited to emit light. Common examples of active light-emitting displays include organic light-emitting diode (OLED) displays and micro light-emitting diode (micro LED) displays.

As users have higher requirement for display brightness and diverse functions, more heat is generated during the use of the displays. If the heat cannot be effectively dissipated, the heat may inevitably cause damage to internal electronic components of the displays, which may not only affect display quality, but also reduce the service life of the displays.

Therefore, there is a need to provide a display module that may effectively and quickly dissipate heat from the displays to improve the display quality and extend the service life of the displays.

### SUMMARY

One aspect of the present disclosure provides a display module. The display module includes a display panel and a heat-dissipation part. The heat-dissipation part at least includes a main-heat-dissipation portion and a sub-heat-dissipation portion; and along a direction perpendicular to a plane of the display panel, the main-heat-dissipation portion is at least partially overlapped with the display panel; along a direction in parallel with the plane of the display panel, the sub-heat-dissipation portion is at least on a side of the main-heat-dissipation portion; and the sub-heat-dissipation portion includes a blade structure; and the main-heat-dissipation portion is connected to the blade structure of the sub-heat-dissipation portion.

Another aspect of the present disclosure provides a vehicle terminal including a display module. The display module includes a display panel and a heat-dissipation part. The heat-dissipation part at least includes a main-heat-dissipation portion and a sub-heat-dissipation portion; and along a direction perpendicular to a plane of the display panel, the main-heat-dissipation portion is at least partially overlapped with the display panel; along a direction in parallel with the plane of the display panel, the sub-heat-dissipation portion is at least on a side of the main-heat-dissipation portion; and the sub-heat-dissipation portion includes a blade structure; and the main-heat-dissipation portion is connected to the blade structure of the sub-heat-dissipation portion.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

FIG. 1 illustrates a planar structural schematic of a display module according to various embodiments of the present disclosure.

FIG. 2 illustrates a planar structural schematic of a heat-dissipation part in FIG. 1.

FIG. 3 illustrates a cross-sectional structural view along an A-A′ direction in FIG. 1.

FIG. 4 illustrates another planar structural schematic of a display module according to various embodiments of the present disclosure.

FIG. 5 illustrates another planar structural schematic of a display module according to various embodiments of the present disclosure.

FIG. 6 illustrates another planar structural schematic of a display module according to various embodiments of the present disclosure.

FIG. 7 illustrates another planar structural schematic of a display module according to various embodiments of the present disclosure.

FIG. 8 illustrates a cross-sectional structural view along a B-B′ direction in FIG. 7.

FIG. 9 illustrates another planar structural schematic of a display module according to various embodiments of the present disclosure.

FIG. 10 illustrates a cross-sectional structural view along a C-C′ direction in FIG. 9.

FIG. 11 illustrates another cross-sectional structural view along an A-A′ direction in FIG. 1.

FIG. 12 illustrates another planar structural schematic of a display module according to various embodiments of the present disclosure.

FIG. 13 illustrates another planar structural schematic of a display module according to various embodiments of the present disclosure.

FIG. 14 illustrates another cross-sectional structural view along an A-A′ direction in FIG. 1.

FIG. 15 illustrates another cross-sectional structural view along an A-A′ direction in FIG. 1.

FIG. 16 illustrates another planar structural schematic of a display module according to various embodiments of the present disclosure.

FIG. 17 illustrates a cross-sectional structural view along a D-D′ direction in FIG. 16.

FIG. 18 illustrates another cross-sectional structural view along a D-D′ direction in FIG. 16.

FIG. 19 illustrates another planar structural schematic of a display module according to various embodiments of the present disclosure.

FIG. 20 illustrates a cross-sectional structural view along an E-E′ direction in FIG. 19.

FIG. 21 illustrates another planar structural schematic of a display module according to various embodiments of the present disclosure.

FIG. 22 illustrates another planar structural schematic of a display module according to various embodiments of the present disclosure.

FIG. 23 illustrates a planar structural schematic of a heat-dissipation part in FIG. 22 after being separated from the display panel.

FIG. 24 illustrates a cross-sectional structural view along an F-F′ direction in FIG. 22.

FIG. 25 illustrates another planar structural schematic of a display module according to various embodiments of the present disclosure.

FIG. 26 illustrates a cross-sectional structural view along a G-G′ direction in FIG. 25.

FIG. 27 illustrates another planar structural schematic of a display module according to various embodiments of the present disclosure.

FIG. 28 illustrates a cross-sectional structural view along an I-I′ direction in FIG. 27.

FIG. 29 illustrates another planar structural schematic of a display module according to various embodiments of the present disclosure.

FIG. 30 illustrates a cross-sectional structural view along a J-J′ direction in FIG. 29.

FIG. 31 illustrates another cross-sectional structural view along an F-F′ direction in FIG. 22.

FIG. 32 illustrates another cross-sectional structural view along an F-F′ direction in FIG. 22.

FIG. 33 illustrates another cross-sectional structural view along an F-F′ direction in FIG. 22.

FIG. 34 illustrates another cross-sectional structural view along a G-G′ direction in FIG. 25.

FIG. 35 illustrates a partial structural schematic of a vehicle terminal according to various embodiments of the present disclosure.

FIG. 36 illustrates a partial structural schematic of a central control region of a vehicle terminal in FIG. 35.

### DETAILED DESCRIPTION

Various exemplary embodiments of the present disclosure are described in detail with reference to accompanying drawings. It should be noted that unless stated otherwise, relative arrangement of assemblies and steps, numerical expressions and values described in those embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be considered as a part of the present disclosure.

In all examples shown and discussed herein, any specific value should be interpreted as merely exemplary, rather than as a limitation. Therefore, other examples in exemplary embodiment may have different values.

It is apparent to those skilled in the art that various modifications and variations may be made in the present disclosure without departing from the spirit or scope of the present disclosure. Therefore, the present disclosure is intended to cover modifications and variations of the present disclosure falling within the scope of corresponding claims (technical solutions to be protected) and their equivalents. It should be noted that, implementation manners provided in embodiment of the present disclosure may be combined with each other if there is no contradiction.

It should be noted that similar reference numerals and letters are configured to indicate similar items in following drawings. Therefore, once an item is defined in one drawing, it does not need to be further discussed in subsequent drawings.

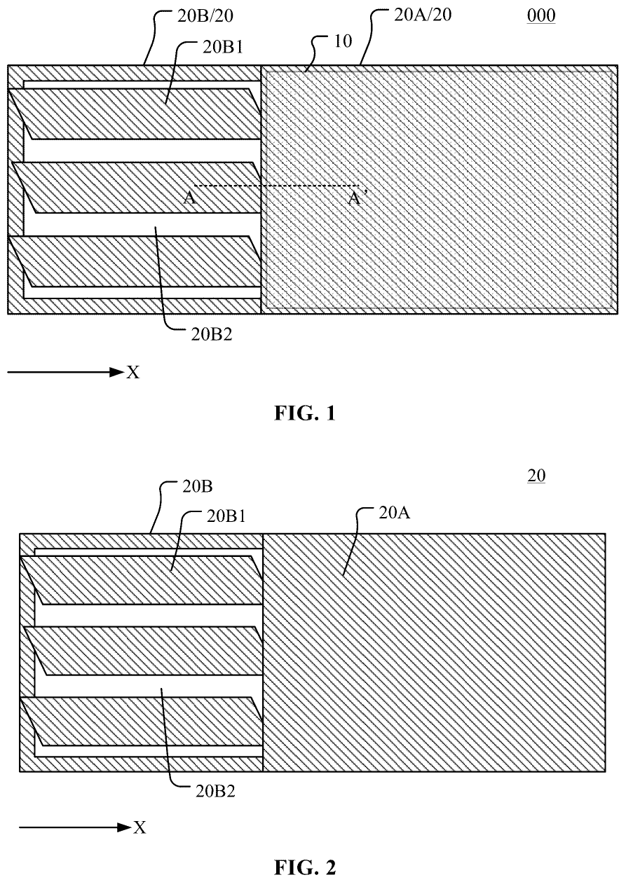

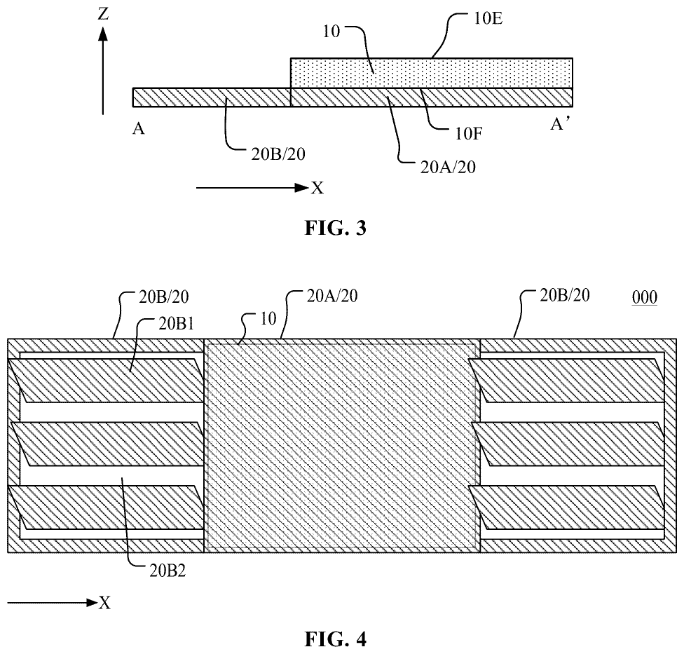

Referring to FIGS. 1-3, FIG. 1 illustrates a planar structural schematic of a display module according to various embodiments of the present disclosure; FIG. 2 illustrates a planar structural schematic of a heat-dissipation part in FIG. 1; and FIG. 3 illustrates a cross-sectional structural view along an A-A′ direction in FIG. 1. A display module 000 provided in embodiments of the present disclosure may include a display panel 10 and a heat-dissipation part 20. The heat-dissipation part 20 may at least include a main-heat-dissipation portion 20A and a sub-heat-dissipation portion 20B. Along the direction Z perpendicular to the plane of the display panel 10, the main-heat-dissipation portion 20A may be at least partially overlapped with the display panel 10. Along the direction X in parallel with the plane of the display panel 10, the sub-heat-dissipation portion 20B may be at least on one side of the main-heat-dissipation portion 20A. The sub-heat-dissipation portion 20B may include a blade structure 20B1. The main-heat-dissipation portion 20A may be connected to the blade structure 20B1 of the sub-heat-dissipation portion 20B.

For example, the display module 000 in embodiments of the present disclosure may include a display panel 10. The display panel 10 may be a liquid crystal display panel, an organic light-emitting diode display panel, a micro-light-emitting diode display panel, or other types of display panels. The type and structure of the display panel 10 may not be limited in embodiments of the present disclosure. During implementation, the type of the display panel 10 may be selected and configured according to requirement of actual application scenario. The display module 000 in embodiments of the present disclosure may also include the heat-dissipation part 20. It may be understood that the heat-dissipation part 20 in embodiments of the present disclosure may be a structure with heat dissipation effect. Optionally, the heat-dissipation part 20 may be made of a high thermal-conductivity material. The high thermal-conductivity material may be a metal sheet (such as a metal copper sheet with high thermal conductivity), or a graphite sheet, or other materials with high thermal conductivity, or a mixture or compound material of two or more high thermal-conductivity materials and the like. During implementation, specific selection may be made based on factors such as actual application requirement and cost performance. The material for the heat-dissipation part 20 may not be limited in embodiments of the present disclosure. The heat-dissipation part 20 may at least include the main-heat-dissipation portion 20A and the sub-heat-dissipation portion 20B, where along the direction Z perpendicular to the plane of the display panel 10, the main-heat-dissipation portion 20A may be at least partially overlapped with the display panel 10. Optionally, the main-heat-dissipation portion 20A may be at least partially overlapped with the display panel 10. It may be understood that along the direction Z perpendicular to the plane of the display panel 10, the main-heat-dissipation portion 20A may be only overlapped with a partial region of the display panel 10. That is, the orthographic projection of the main-heat-dissipation portion 20A on the plane of the display panel 10 may only cover a partial region of the display panel 10, such as some regions that are easy to generate high heat. It may be also understood that along the direction Z perpendicular to the plane of the display panel 10, the main-heat-dissipation portion 20A may be overlapped with all regions of the display panel 10, that is, the orthographic projection of the main-heat-dissipation portion 20A on the plane of the display panel 10 may cover all regions of the display panel 10. In drawings in embodiments of the present disclosure, the main-heat-dissipation portion 20A may be overlapped with all regions of the display panel 10 along the direction Z perpendicular to the plane of the display panel 10, which is taken as an example for illustration. In order to clearly illustrate the structure of the display panel 10 and the main-heat-dissipation portion 20A in embodiments of the present disclosure, transparency filling is performed in FIG. 1. During implementation, it only needs to satisfy that along the direction Z perpendicular to the plane of the display panel 10, the main-heat-dissipation portion 20A may be at least partially overlapped with the display panel 10, and the orthographic projection of the main-heat-dissipation portion 20A on the plane of the display panel 10 may be within the range where the display panel 10 is located.

It may be understood that the display panel 10 may include a light-exiting surface 10E and a backlight surface 10F which are arranged oppositely. The light-exiting surface 10E of the display panel 10 may be understood as a side surface of the display panel 10 for displaying images; and the backlight surface 10F of the display panel 10 may be another side surface of the display panel 10 opposite to the light-exiting surface 10E. In drawings of embodiments of the present disclosure, the main-heat-dissipation portion 20A may be on the side of the backlight surface 10F of the display panel 10 along the direction Z perpendicular to the plane of the display panel 10, which is taken as an example for illustration. In order to clearly illustrate the structure of the display panel 10 and the main-heat-dissipation portion 20A in embodiments of the present disclosure, transparency filling is performed in FIG. 1. During implementation, the main-heat-dissipation portion 20A may also be at other positions of the display panel 10. For example, the main-heat-dissipation portion 20A may also be on the side of the light-exiting surface 10E of the display panel 10, or inside the display panel 10, or at other positions of the display panel 10 that do not affect the display, which may refer to subsequent embodiments for understanding and may not be described in detail herein.

For the structure of the heat-dissipation part 20 in embodiments of the present disclosure, along the direction Z perpendicular to the plane of the display panel 10, the main-heat-dissipation portion 20A may be at least partially overlapped with the display panel 10. The main-heat-dissipation portion 20A may be configured to conduct heat generated in the usage of the display panel 10. Through the configuration that the main-heat-dissipation portion 20A is at least partially overlapped with the display panel 10, the heat generated in the usage of the display panel 10 may be conducted through the main-heat-dissipation portion 20A of the heat-dissipation part 20. In addition, along the direction X in parallel with the plane of the display panel 10, the sub-heat-dissipation portion 20B included in the heat-dissipation part 20 may be at least on one side of the main-heat-dissipation portion 20A. The sub-heat-dissipation portion 20B may be understood as a region of the heat-dissipation part 20 configured on the periphery of the display panel 10. After the heat generated in the usage of the display panel 10 is conducted and dissipated through the main-heat-dissipation portion 20A, the heat may be further conducted to the sub-heat-dissipation portion 20B in the peripheral region of the display panel 10 and may be effectively dissipated in the peripheral region of the display panel 10, which may be beneficial for faster heat dissipation and improving display quality.

Optionally, in embodiments of the present disclosure, along the direction Z perpendicular to the plane of the display panel 10, the sub-heat dissipation portion 20B may not be overlapped with the display panel 10. After the heat generated in the usage of the display panel 10 is conducted and dissipated through the main-heat-dissipation portion 20A, the heat may be further quickly conducted through the sub-heat dissipation portion 20B to a position that may not be overlapped with the display panel 10, which may avoid heat accumulation in the region where the display panel 10 is located, thereby achieving desirable heat dissipation effect.

It may be understood that the direction X in parallel with the plane of the display panel 10 in embodiments of the present disclosure may be understood as any direction in parallel with the plane of the display panel 10 and may not be necessary to be a horizontal or vertical direction. A direction X in FIG. 1 in one embodiment may be only exemplary; that is, the direction X in parallel with the plane of the display panel 10 in one embodiment may be any divergent direction in parallel with the plane of the display panel 10.

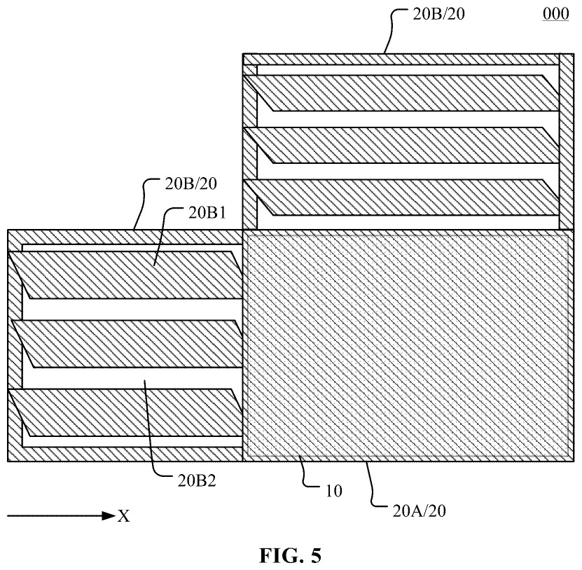

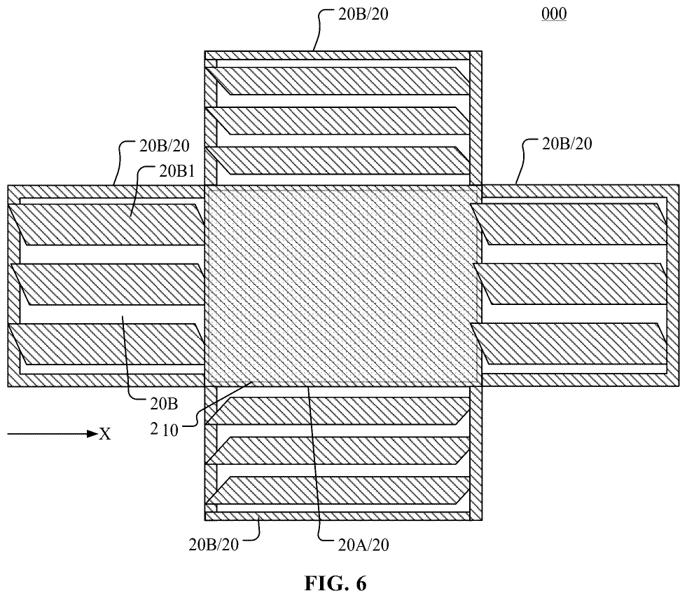

Optionally, referring to FIGS. 1 and 4-6, FIG. 4 illustrates another planar structural schematic of a display module according to various embodiments of the present disclosure; FIG. 5 illustrates another planar structural schematic of a display module according to various embodiments of the present disclosure; and FIG. 6 illustrates another planar structural schematic of a display module according to various embodiments of the present disclosure. In order to clearly illustrate the structure of the display panel 10 and the main-heat-dissipation portion 20A in one embodiment, transparency filling is performed in FIGS. 4-6. In one embodiment, along the direction X in parallel with the plane of the display panel 10, the sub-heat dissipation portion 20B may be at least on one side of the main-heat-dissipation portion 20A. It may be understood that the sub-heat-dissipation portion 20B may be only on one side of the main-heat-dissipation portion 20A (as shown in FIG. 1), or the sub-heat-dissipation portion 20B may be on two opposite sides of the main-heat-dissipation portion 20A (as shown in FIG. 4), or the sub-heat-dissipation portion 20B may be on two adjacent sides of the main-heat-dissipation portion 20A (as shown in FIG. 5), or the sub-heat-dissipation portion 20B may surround the main-heat-dissipation portion 20A (as shown in FIG. 6). In such way, the sub-heat-dissipation portion 20B may have more uniform heat guiding and dissipating effect on the main-heat-dissipation portion 20A. The installation position, installation range and installation region of the sub-heat-dissipation portion 20B may not be limited in embodiments of the present disclosure, which only needs to satisfy that along the direction X in parallel with the plane of the display panel 10, the sub-heat-dissipation portion 20B may be at least on one side of the main-heat-dissipation portion 20A and continue to conduct the heat conducted by the main-heat-dissipation portion 20A in the region of the display panel 10 to the periphery of the display panel 10 to facilitate rapid heat dissipation.

The sub-heat-dissipation portion 20B in embodiments of the present disclosure may include the blade structure 20B1, and the main-heat-dissipation portion 20A may be connected to the blade structure 20B1 of the sub-heat-dissipation portion 20B. The blade structure 20B1 may be understood as a sheet-shaped structure similar to a fan blade or a strip-shaped structure like an air-conditioning outlet blade. The sub-heat-dissipation portion 20B may be designed to include the blade structure 20B1, and a hollow region 20B2 of the sub-heat-dissipation portion 20B may be formed by the blade structures 20B1. Therefore, while increasing the heat dissipation area of the sub-heat-dissipation portion 20B, the heat may also be conducted through the hollow region 20B2 around the blade structure 20B1 by hollowing out of the sub-heat-dissipation portion 20B. That is, the hollow region 20B2 may provide a heat conduction path, which may be beneficial for further accelerating the dissipation speed of heat conducted to the sub-heat-dissipation portion 20B. Furthermore, the heat generated in the region of the display panel 10 and conducted by the main-heat-dissipation portion 20A may be more effectively dissipated through the sub-heat-dissipation portion 20B, which may be beneficial for increasing overall heat dissipation speed of the display module 000, improving the display quality, and ensuring the service life of the module.

When the display module 000 in embodiments of the present disclosure is used, the heat generated by the display panel 10 may be quickly conducted through the main-heat-dissipation portion 20A at least partially overlapped with the display panel 10, and then the heat may be further conducted to the blade structure 20B1 of the sub-heat-dissipation portion 20B through the sub-heat-dissipation portion 20B connected to the main-heat-dissipation portion 20A. Since the sub-heat-dissipation portion 20B is designed to include the blade structure 20B1, the area of the hollow region 20B2 formed by the sub-heat-dissipation portion 20B may be increased. Therefore, the heat dissipation area of the sub-heat-dissipation portion 20B may be increased, the heat dissipation speed of the sub-heat-dissipation portion 20B may be accelerated, and the heat generated during the usage of the final display panel 10 may be quickly and effectively dissipated through the sub-heat-dissipation portion 20B, which may be beneficial for not only improving the display quality of the module, but also ensuring the service life of the module. Moreover, the heat-dissipation part 20 in embodiments of the present disclosure may occupy less module space along the thickness direction of the module. Compared with the design structure in the existing technology that a cooling chassis or a cooling fan is installed behind the display panel, the configuration of the heat-dissipation part 20 in embodiments of the present disclosure may not only save cost and but also have simple structure. The space occupied, especially along the thickness direction of the module, may be relatively small, which may effectively avoid large-volume heat-dissipation part from affecting overall layout of the module, and may be beneficial for simplifying overall structure of the module.

It may be understood that in embodiments of the present disclosure, the main-heat-dissipation portion 20A of the heat-dissipation part 20 may be connected to the blade structure 20B1 of the sub-heat-dissipation portion 20B; and the main-heat-dissipation portion 20A and the blade structure 20B1 of the sub-heat-dissipation portion 20B may together form a single-piece structure, which may not only facilitate heat conduction, but also be beneficial for improving the process efficiency of the heat-dissipation part 20 and saving formation cost.

It should be noted that in order to clearly distinguish the main-heat-dissipation portion 20A and the sub-heat-dissipation portion 20B in drawings of above-mentioned embodiments and subsequent embodiments, the single-piece structure is not shown in drawings, but the main-heat-dissipation portion 20A and the blade structure 20B1 of the sub-heat-dissipation portion 20B may be understood as the single-piece structure.

It may be understood that embodiments of the present disclosure may not limit the number of blade structures 20B1 included in the sub-heat-dissipation portion 20B. The sub-heat-dissipation portion 20B may include at least one blade structure 20B1 and may also include a large number of blade structures 20B1. In addition, the blade structure 20B1 may be a sheet-shaped structure, which is taken as an example for illustration in embodiments of the present disclosure. During implementation, the blade structure 20B1 included in the sub-heat-dissipation portion 20B may include, but may not be limited to, such shape, and may also be designed in other shapes, which only needs to satisfy that the design of the sub-heat-dissipation portion 20B including the blade structure 20B1 may increase the hollow area formed by the sub-heat-dissipation portion 20B and achieve the effect of accelerating the heat dissipation speed.

Optionally, the blade structure 20B1 in embodiments of the present disclosure may be understood as a strip-shaped structure similar to an air-conditioning outlet blade, such that the blade structure 20B1 may be movable relative to entire frame of the heat-dissipation part 20. Through the movement of the blade structure 20B1, the size of the hollow region 20B2 formed by the blade structure 20B1 in the sub-heat-dissipation portion 20B may be controlled, thereby achieving rapid and effective heat dissipation at the position of the sub-heat-dissipation 20B.

It should be noted that a block is used to represent the display panel 10 in figures of embodiments of the present disclosure. During implementation, the structure of the display panel 10 may be configured with film layers and other structures according to the type of the display panel 10, which may refer to the structure of the display panel 10 in the existing technology and may not be described in detail herein.

Optionally, referring to FIGS. 1-3, in one embodiment, the main-heat-dissipation portion 20A of the heat-dissipation part 20 may be disposed on the side of the backlight surface 10F of the display panel 10. The space on the side of the backlight surface 10F of the display panel 10 is relatively large. Therefore, by disposing the main-heat-dissipation portion 20A on the side of the backlight surface 10F of the display panel 10, the area of the main-heat-dissipation portion 20A may be disposed as large as possible without affecting the displayed image on the side of the light-exiting surface 10E of the display panel 10. Moreover, the main-heat-dissipation portion 20A may be disposed on the side of the backlight surface 10F of the display panel 10 which may not affect the displayed image on the side of the light-exiting surface 10E of the display panel 10, such that the main-heat-dissipation portion 20A may be formed using a wide range of materials. When the display panel 10 is used, the heat generated may be conducted through the main-heat-dissipation portion 20A with large area disposed on the side of the backlight surface 10F of the display panel 10 and conducted to the blade structure 20B1 of the sub-heat dissipation portion 20B, which may achieve accelerating the heat dissipation speed.

Optionally, as shown in FIGS. 1-3, along the direction Z perpendicular to the plane of the display panel 10, the main-heat-dissipation portion 20A may cover the display panel 10.

In one embodiment, it describes that the main-heat-dissipation portion 20A may be configured with large area as possible. For example, along the direction Z perpendicular to the plane of the display panel 10, the main-heat-dissipation portion 20A may cover the display panel 10. That is, the orthographic projection of the main-heat-dissipation portion 20A on the plane of the display panel 10 may cover entire region where the display panel 10 is located. At this point, overall shape of the main-heat-dissipation portion 20A may be a full-surface structure without any hollows. In such way, the main-heat-dissipation portion 20A may have a larger heat dissipation area for the display panel 10, which may effectively dissipate the heat generated in all regions of the display panel 10 with desirable heat dissipation effect; in addition if the main-heat-dissipation portion 20A with large area is a full-surface and gap-free structure, the main-heat-dissipation portion 20A may occupy less space along the thickness of the module, which may make the structure to be simple and being beneficial for saving cost.

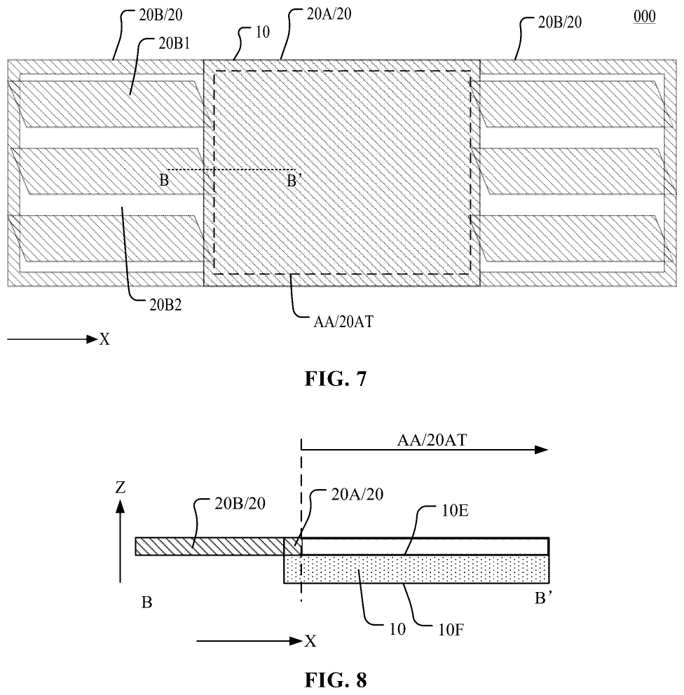

Optionally, referring to FIGS. 7-8, FIG. 7 illustrates another planar structural schematic of a display module according to various embodiments of the present disclosure; and FIG. 8 illustrates a cross-sectional structural view along a B-B′ direction in FIG. 7. In order to clearly illustrate the structure of the display panel 10 and the main-heat-dissipation portion 20A in embodiments of the present disclosure, transparency filling is performed in FIG. 7. In one embodiment, the main-heat-dissipation portion 20A may be disposed on the side of the light-exiting surface 10E of the display panel 10.

The main-heat-dissipation portion 20A may include a light-transmitting region 20AT. Along the direction Z perpendicular to the plane of the display panel 10, the main-heat-dissipation portion 20A at the light-transmitting region 20AT may be overlapped with the display region AA of the display panel 10. The main-heat-dissipating portion 20A at the light-transmitting region 20AT may be transparent.

In one embodiment, it describes that the main-heat-dissipation portion 20A of the heat-dissipation part 20 may be disposed on the light-exiting surface 10E of the display panel 10. At this point, the main-heat-dissipation portion 20A may cover the display panel 10. That is, the orthographic projection of the main-heat-dissipation portion 20A on the plane of the display panel 10 may cover entire region where the display panel 10 is located. Overall shape of the main-heat-dissipation portion 20A may be a full-surface structure without any hollows. In such way, the main-heat-dissipation portion 20A may have a larger heat dissipation area for the display panel 10, which may effectively dissipate the heat generated in all regions of the display panel 10 with desirable heat dissipation effect; in addition if the main-heat-dissipation portion 20A with large area is a full-surface and gap-free structure, the main-heat-dissipation portion 20A may occupy less space along the thickness of the module, which may make the structure to be simple and being beneficial for saving cost.

In embodiments of the present disclosure, when the main-heat-dissipation portion 20A of the heat-dissipation part 20 is disposed on the side of the light-exiting surface 10E of the display panel 10, the main-heat-dissipation portion 20A may need to be configured with the light-transmitting region 20AT. The main-heat-dissipation portion 20A at the light-transmitting region 20AT may be understood as transparent. In FIG. 8, unfilled pattern of the main-heat-dissipation portion 20A at the light-transmitting region 20AT may indicate transparent and may not indicate that the main-heat-dissipation portion 20A at the light-transmitting region 20AT is hollowed out. In addition, along the direction Z perpendicular to the plane of the display panel 10, the main-heat-dissipation portion 20A at the light-transmitting region 20AT may be overlapped with the display region AA of the display panel 10. In such way, the main-heat-dissipation portion 20A may effectively dissipate heat in all regions of the display panel 10 and may also prevent the main-heat-dissipation portion 20A from affecting normal display at the display region AA of the display panel 10 on the side of the light-exiting surface 10E of the display panel 10.

Furthermore, optionally, when the main-heat-dissipation portion 20A in embodiments of the present disclosure is disposed on the side of the light-exiting surface of the display panel 10, at least the main-heat-dissipation portion 20A at the light-transmitting region 20AT may be made of a material with high light transmittance. That is, the material of the main-heat-dissipation portion 20A at the light-transmitting region 20AT may not only have high thermal conductivity and also have the light transmittance greater than or equal to 50%, which may improve the transparency of the main-heat-dissipation portion 20A at the light-transmitting region 20AT and ensure that the image at the display region AA of the display panel 10 is normally displayed.

Furthermore, optionally, the area at the light-transmitting region 20AT of the main-heat-dissipation portion 20A may be slightly larger than the area of the display region AA of the display panel 10. That is, when the main-heat-dissipation portion 20A is disposed on the side of the light-exiting surface 10E of the display panel 10, the light-transmitting region 20AT of the main-heat-dissipation portion 20A may be slightly outside the display region AA of the display panel 10 through an alignment process, which may prevent the misalignment of the heat-dissipation part 20 and the display panel 10 from causing the region of the main-heat-dissipation portion 20A except the light-transmitting region 20AT to block the display region AA of the display panel 10, thereby being beneficial for further ensuring visual effect of the display region AA of the display panel 10.

It should be noted that embodiments of the present disclosure may not limit the material of the main-heat-dissipation portion 20A. During implementation, the formation material may be selected according to factors such as the application scenario of the module and the cost-effectiveness of the material, which only needs to satisfy that the material of the main-heat-dissipation portion 20A at the light-transmitting region 20AT may be a transparent material with high thermal conductivity.

In some other optional embodiments, the material of the main-heat-dissipation portion 20A at the light-transmitting region 20AT may be different from the material of remaining regions of the heat-dissipation part 20, which only needs to ensure that the main-heat-dissipating portion 20A at the light-transmitting region 20AT may be transparent. Or in some other optional embodiments, the material of the main-heat-dissipation portion 20A at the light-transmitting region 20AT may be same as the material of remaining regions of the heat-dissipation part 20, thereby being beneficial for simplifying the formation process of the heat-dissipation part 20, improving the process efficiency of the heat-dissipation part 20 and saving formation cost, which may not be limited in embodiments of the present disclosure.

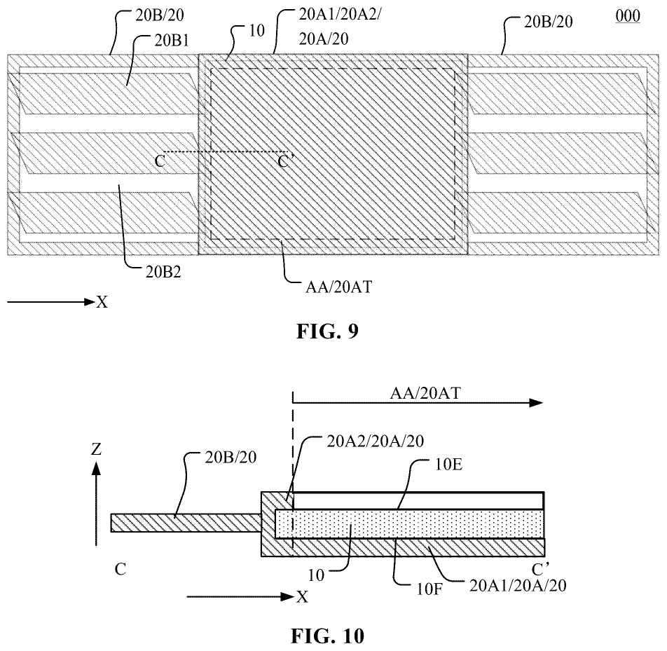

In some optional embodiments, referring to FIGS. 9-10, FIG. 9 illustrates another planar structural schematic of a display module according to various embodiments of the present disclosure; and FIG. 10 illustrates a cross-sectional structural view along a C-C′ direction in FIG. 9. In order to clearly illustrate the structure of the display panel 10 and the main-heat-dissipation portion 20A in embodiments of the present disclosure, transparency filling is performed in FIG. 9. In one embodiment, the main-heat-dissipation portion 20A of the heat-dissipation part 20 may include two portions such as the first main-heat-dissipation portion 20A1 and the second main-heat-dissipation portion 20A2. The first main-heat-dissipation portion 20A1 and the second main-heat-dissipation portion 20A2 may be both connected to the sub-heat-dissipation portion 20B. The first main-heat-dissipation portion 20A1 may be disposed on the side of the backlight surface 10F of the display panel 10, and the second main-heat-dissipation portion 20A2 may be disposed on the side of the light-exiting surface 10E of the display panel 10, which may be understood as a structure that the display panel 10 may be wrapped by the first main-heat-dissipation portion 20A1 and the second main-heat-dissipation portion 20A2. The second main-heat-dissipation portion 20A2 may include the light-transmitting region 20AT in above-mentioned embodiments; and along the direction Z perpendicular to the plane of the display panel 10, the second main-heat dissipation portion 20A2 at the light-transmitting region 20AT may be overlapped with the display region AA of the display panel 10. The second main-heat-dissipation portion 20A2 at the light-transmitting region 20AT may be transparent to prevent the configuration of the second main-heat-dissipation portion 20A2 from affecting the visibility of the displayed images in the display region AA of the display panel 10. In FIG. 10, unfilled pattern of the second main-heat-dissipation portion 20A2 at the light-transmitting region 20AT may indicate transparent and may not indicate that the main-heat-dissipating portion 20A at the light-transmitting region 20AT is hollowed out. In one embodiment, by disposing the main-heat-dissipation portion 20A (the first main-heat dissipation portion 20A1 and the second main-heat dissipation portion 20A2) on both the light-exiting surface 10E and the backlight surface 10F of the display panel 10, the area of the heat-dissipation part 20 in the region where the display panel 10 is located may be further increased; and the heat dissipation speed of the main-heat-dissipation portion 20A for the heat generated in the usage of the display panel 10 may be further increased, thereby further effectively improving the heat dissipation effect.

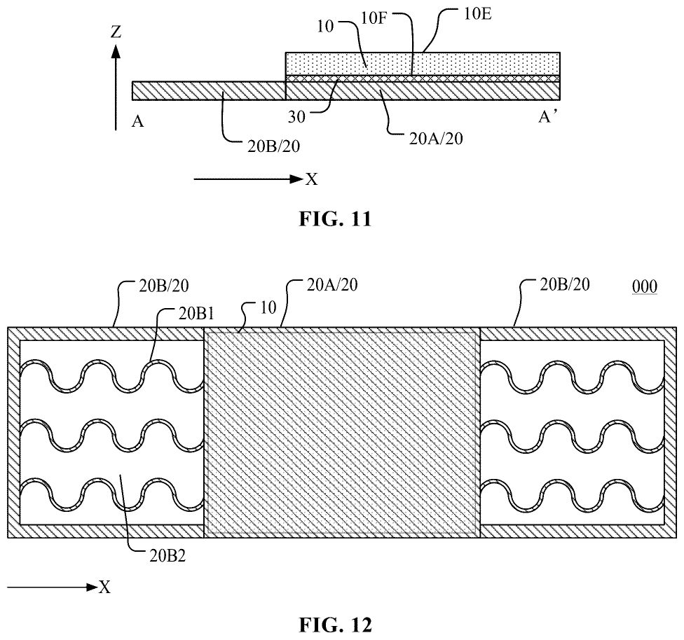

In some optional embodiments, referring to FIGS. 1 and 11, FIG. 11 illustrates another cross-sectional structural view along the A-A′ direction in FIG. 1. In one embodiment, the main-heat-dissipation portion 20A may be fixed to the display panel 10 through a thermal conductive adhesive layer 30.

In one embodiment, it describes that the main-heat-dissipation portion 20A of the heat-dissipation part 20 may be at least partially overlapped with the display panel 10 along the direction Z perpendicular to the plane of the display panel 10. For example, the main-heat-dissipation portion 20A may be disposed on the side of the backlight surface 10F of the display panel 10. In addition, when the main-heat-dissipation portion 20A covers the display panel 10, the main-heat-dissipation portion 20A may be in close contact with the backlight surface 10F (the light-exiting surface in other embodiments) of the display panel 10 through the thermal conductive adhesive layer 30. The thermal conductive adhesive layer 30 may be a thin gel material with desirable thermal conductivity, which may not only ensure the fixing effect between the heat-dissipation part 20 and the display panel 10, but also reduce the heat conduction path in the process of heat conduction from the display panel 10 to the main-heat-dissipation portion 20A, thereby being beneficial for conducting heat quickly and further improving the heat dissipation effect of the heat-dissipation part on the display panel 10.

It may be understood that the thickness, the material and the like of the thermal conductive adhesive layer 30. During implementation, the thermal conductive adhesive layer 30 may be configured by referring to the fixed fit stability between the main-heat-dissipation portion 20A and the display panel 10 and the thermal conductivity of the material itself.

It should be noted that when the main-heat-dissipation portion 20A is disposed on the side of the backlight surface 10F of the display panel 10 and the main-heat-dissipation portion 20A covers the display panel 10, the main-heat-dissipation portion 20A and the backlight surface 10F of the display panel 10 may also include other film layers in addition to the thermal conductive adhesive layer 30, such as certain buffer protective layers and the like, which may be configured to buffer and protect the structure on the side of the backlight surface 10F of the display panel 10 (such as a bent flexible circuit board, a drive circuit board and the like), which may not be described in detail in embodiments of the present disclosure.

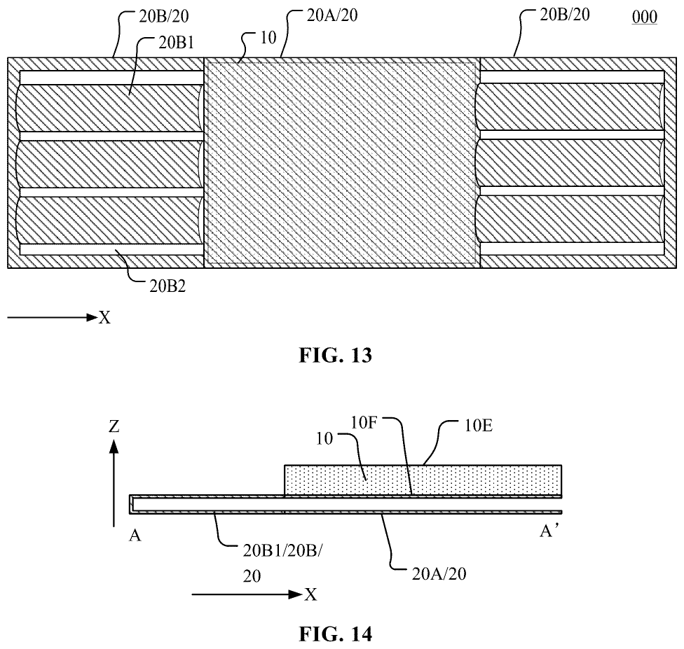

In some optional embodiments, referring to FIGS. 4, 12 and 13, FIG. 12 illustrates another planar structural schematic of a display module according to various embodiments of the present disclosure; and FIG. 13 illustrates another planar structural schematic of a display module according to various embodiments of the present disclosure. In order to clearly illustrate the structure of the display panel 10 and the main-heat-dissipation portion 20A in embodiments of the present disclosure, transparency filling is performed in FIGS. 12-13. In one embodiment, the blade structure 20B1 of the sub-heat-dissipation portion 20B may be any one of a flat block shape, a wavy shape, or a cylindrical shape.

In one embodiment, it describes that in the structure of the heat-dissipation part 20, the shape of the blade structure 20B1 included in the sub-heat-dissipation portion 20B may be a flat block shape (as shown in FIG. 4), thereby being beneficial for reducing the formation difficulty of the sub-heat-dissipation portion 20B and improve the process efficiency; or the blade structure 20B1 included in the sub-heat-dissipation portion 20B may be a wavy shape (as shown in FIG. 12) or a cylindrical shape (as shown in FIG. 13). By changing the design shape of the blade structure 20B1, the heat dissipation area of the blade structure 20B1 may be increased, which may be beneficial for further improving the heat dissipation performance and heat dissipation speed of the sub-heat-dissipation portion 20B.

In some optional embodiments, referring to FIGS. 1 and 14, FIG. 14 illustrates another cross-sectional structural view along the A-A′ direction in FIG. 1. In one embodiment, the main-heat-dissipation portion 20A of the heat-dissipation part 20 may include a hollow structure, and the blade structure 20B1 may include a hollow structure.

The hollow structure included in the blade structure 20B1 and the hollow structure included in the main-heat-dissipation portion 20A may be connected to communicate with each other.

In one embodiment, it describes that the heat-dissipation part 20 may be designed to include a hollow structure, that is, the main-heat-dissipation portion 20A of the heat-dissipation part 20 may include a hollow structure. The blade structure 20B1 included in the sub-heat-dissipation portion 20B of the heat-dissipation part 20 may also include a hollow structure. In addition, the hollow structure included in the blade structure 20B1 and the hollow structure included in the main-heat-dissipation portion 20A may be connected to communicate with each other, and the hollow main-heat-dissipation portion 20A with large area may be connected with the hollow blade structure 20B1. By forming the hollow interior and adding gas, the gas in the closed space may form convection to increase the heat conduction speed of the heat-dissipation part 20, which may further improve the heat dissipation effect of the display panel 10.

It may be understood that the main-heat-dissipation portion 20A of the heat-dissipation part 20 may include the hollow structure. When the blade structure 20B1 includes the hollow structure, the heat-dissipation part 20 may be a VC plate (a vapor chamber, also refer to a flat heat pipe in the existing technology) which is a desirable material for uniform heat dissipation. The heat-dissipation part 20 may effectively improve heat dissipation efficiency and also ensure uniform and stable heat dissipation. It may be understood that although the heat-dissipation part 20 is an internal hollow structure, overall thickness (such as the thickness of the main-heat-dissipation portion 20A along the direction Z perpendicular to the plane of the display panel 10) of the heat-dissipation part 20 may be thinner, thereby providing desirable heat dissipation effect.

Optionally, as shown in FIGS. 1 and 14, liquid or gas (not shown in FIGS. 1 and 14) may be configured in both the hollow structure included in the main-heat-dissipation portion 20A and the hollow structure included in the blade structure 20B1. In one embodiment, the hollow structure included in the blade structure 20B1 and the hollow structure included in the main-heat-dissipation portion 20A may be connected to communicate with each other. The hollow main-heat-dissipation portion 20A with large area may be connected with the hollow blade structure 20B1. By forming the hollow interior and adding gas (such as condensed gas) or liquid (such as water or volatile liquid), the gas or liquid in the hollow and closed space of the heat-dissipation part 20 may form convection, and water or volatile liquid may accelerate heat conduction and dissipation in the hollow space, which may further improve the heat dissipation effect of the display panel 10.

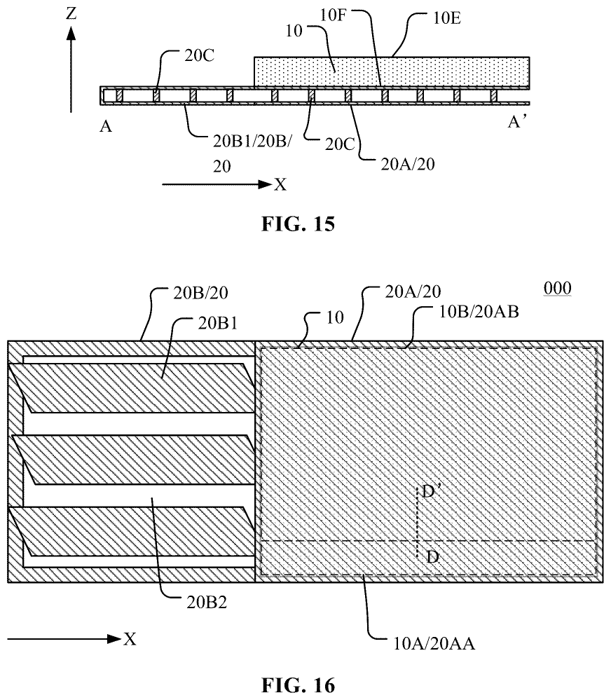

Optionally, referring to FIGS. 1 and 15, FIG. 15 illustrates another cross-sectional structural view along the A-A′ direction in FIG. 1. In one embodiment, the main-heat-dissipation portion 20A of the heat-dissipation part 20 may include a hollow structure, and the blade structure 20B1 may include a hollow structure; the hollow structure included in the blade structure 20B1 and the hollow structure included in the main-heat-dissipation portion 20A may be connected to communicate with each other; the hollow structure included in the main-heat-dissipation portion 20A may include a support part 20C, or the hollow structure included in the blade structure 20B1 may include a support part 20C, or the hollow structure included in the main-heat-dissipation portion 20A and the hollow structure included in the blade structure 20B1 may each include a support part 20C; and the support part 20C may be fixedly connected to the heat-dissipation part 20.

In one embodiment, it describes that the heat-dissipation part 20 may be designed to include a hollow structure, that is, the main-heat-dissipation portion 20A of the heat-dissipation part 20 may include a hollow structure. The blade structure 20B1 included in the sub-heat-dissipation portion 20B of the heat-dissipation part 20 may be also a hollow structure, and the hollow structure included in the blade structure 20B1 and the hollow structure included in the main-heat-dissipation portion 20A may be connected to communicate with each other. The hollow main-heat-dissipation portion 20A with large area may be connected with the hollow blade structure 20B1. By forming the hollow interior and adding gas, the gas in the closed space may form convection to increase the heat conduction speed of the heat-dissipation part 20, and further improve the heat dissipation effect of the display panel 10. In addition, in order to ensure the stability of the heat-dissipation part 20, the support 20C may be disposed in the internal hollow region to prevent the hollow main-heat-dissipation portion 20A and the hollow sub-heat-dissipation portion 20B from collision due to the hollow structures, which may ensure the circulation of the gas or liquid inside the hollow structures, thereby ensuring the heat dissipation effect of the heat-dissipation part 20.

Optionally, the support part 20C in one embodiment may be fixedly connected to the heat-dissipation part 20 with hollow interior. It may be understood that the support part 20C and the heat-dissipation part 20 may be formed into a single piece; or after the support part 20C is formed separately, the support part 20C may be fixedly connected to the heat-dissipation part 20, which may not be limited in one embodiment and only needs to satisfy that the support part 20C is inside the hollow heat-dissipation part 20 to achieve desirable supporting effect.

Optionally, the support part 20C in one embodiment may have a cylindrical structure to ensure desirable internal circulation of the hollow heat-dissipation part 20.

Optionally, the materials of the support part 20C and the heat-dissipation part 20 in one embodiment may be the same; that is, the support part 20C may also be made of a material with high thermal conductivity to improve the heat dissipation effect of entire heat-dissipation part 20. It should be noted that drawings in embodiments of the present disclosure may only use different filling patterns to distinguish the structures of the support part 20C and the heat-dissipation part 20, which may not indicate that the support part 20C and the heat-dissipation part 20 must be made of different materials. Furthermore, since the support part 20C needs to have desirable supporting effect, the material of the support part 20C may need to ensure high thermal conductivity and high strength to avoid deformation of the support part 20C inside the hollow heat-dissipation part 20. Therefore, the support part 20C may need to be made of a material with high thermal conductivity and high strength, which may be beneficial for improving the heat dissipation effect and ensuring the stability of entire heat-dissipation part 20.

It may be understood that the shape, the volume, the distribution density and the like of the support part 20C may not be limited in embodiments of the present disclosure. The shape of the support part 20C may be cylindrical or other shapes, which only needs to satisfy that the support part 20C may desirably support the internal hollow heat-dissipation part 20 and may not affect the circulation of gas or liquid in the internal hollow structure.

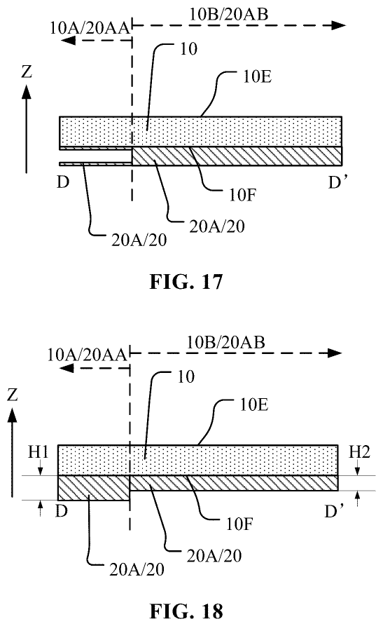

In some optional embodiments, referring to FIGS. 16 and 17, FIG. 16 illustrates another planar structural schematic of a display module according to various embodiments of the present disclosure; and FIG. 17 illustrates a cross-sectional structural view along a D-D′ direction in FIG. 16. In order to clearly illustrate the structure of the display panel 10 and the main-heat-dissipation portion 20A in one embodiment, transparency filling is performed in FIG. 16. In one embodiment, the display panel 10 may include the first region 10A and the second region 10B.

The main-heat-dissipation portion 20A may include the third region 20AA and the fourth region 20AB. Along the direction Z perpendicular to the plane of the display panel 10, the display panel 10 at the first region 10A may be overlapped with the main-heat-dissipation portion 20A at the third region 20AA; and the display panel 10 at the second region 10B may be overlapped with the main-heat-dissipation portion 20A at the fourth region 20AB.

The thermal conductivity of the main-heat-dissipation portion 20A at the third region 20AA may be greater than the thermal conductivity of the main-heat-dissipation portion 20A at the fourth region 20AB.

In one embodiment, it describes that the main-heat-dissipation portion 20A of the heat-dissipation part 20 may be configured to be overlapped with the display panel 10. If the main-heat-dissipation portion 20A covers the region where the display panel 10 is located, the heat dissipation performance of different regions of the main-heat-dissipation portion 20A may be designed differently. The heat generated by the display panel 10 may be unevenly distributed when the display panel 10 is used. For example, the position where a driving circuit such as a driving chip and the like is disposed for inputting driving signals may generate relatively high heat with relatively high temperature. Therefore, in one embodiment, different regions of the main-heat-dissipation portion 20A may be designed differently according to the difference in heat generated in different regions of the display panel 10. For example, the display panel 10 may include the first region 10A and the second region 10B. The first region 10A may be a region that easily generates a large amount of heat when the display panel 10 is used, such as a region where a driving circuit such as a driving chip and the like is configured. The second region 10B may be a region that generates a small amount of heat when the display panel 10 is used. That is, when the display panel 10 is used, the heat in the first region 10A may be greater than the heat in the second region 10B. At this point, the main-heat-dissipation portion 20A may be configured with the third region 20AA and the fourth region 20AB. In addition, along the direction Z perpendicular to the plane of the display panel 10, the display panel 10 at the first region 10A may be overlapped with the main-heat-dissipation portion 20A at the third region 20AA; and the display panel 10 at the second region 10B may be overlapped with the main-heat-dissipation portion 20A at the fourth region 20AB. That is, the main-heat-dissipation portion 20A at the third region 20AA may correspond to the display panel 10 at the first region 10A and dissipate the heat generated by the display panel 10 at the first region 10A; and the main-heat-dissipation portion 20A at the fourth region 20AB may correspond to the display panel 10 of the second region 10B and dissipate the heat generated by the display panel 10 at the second region 10B. The thermal conductivity of the main-heat-dissipation portion 20A at the third region 20AA may be configured to be greater than the thermal conductivity of the main-heat-dissipation portion 20A at the fourth region 20AB. Therefore, the heat dissipation speed and heat dissipation efficiency of the main-heat-dissipation portion 20A at the third region 20AA for the display panel 10 at the first region 10A may be improved; and the heat generated by the display panel 10 at the first region 10A with a large amount of heat may be conducted to the blade structure 20B1 of the sub-heat-dissipation portion 20B as quickly as possible. Furthermore, the blade structure 20B1 may dissipate heat faster and more effectively, thereby improving the heat dissipation effect of the module.

It should be noted that the configuration manner that the thermal conductivity of the main-heat-dissipation portion 20A at the third region 20AA is greater than the thermal conductivity of the main-heat-dissipation portion 20A at the fourth region 20AB may not be limited in one embodiment. The thermal conductivity of the main-heat-dissipation portion 20A at the third region 20AA may be greater than the thermal conductivity of the main-heat-dissipation portion 20A at the fourth region 20AB, which may be understood that for same amount of heat, the heat dissipation efficiency of the main-heat-dissipation portion 20A at the third region 20AA may be greater than the heat dissipation efficiency of the main-heat-dissipation portion 20A at the fourth region 20AB. Optionally, During implementation, the structure of the main-heat-dissipation portion 20A at the third region 20AA and the main-heat-dissipation portion 20A at the fourth region 20AB may be configured to be different, thereby realizing that the thermal conductivity of the main-heat-dissipation portion 20A at the third region 20AA is greater than that of the main-heat-dissipation portion 20A at the fourth region 20AB. For example, as shown in FIG. 17, the main-heat-dissipation portion 20A at the third region 20AA may be configured to include an internal hollow structure, and gas or liquid may be configured in the internal hollow structure. The thermal conductivity of the main-heat-dissipation portion 20A at the third region 20AA may be enhanced through the gas or liquid movement. In addition, the interior of the main-heat-dissipation portion 20A at the fourth region 20AB may be a non-hollow structure. For example, the main-heat-dissipation portion 20A at the fourth region 20AB may be a plate-shaped solid structure. In such way, the thermal conductivity of the main-heat-dissipation portion 20A at the fourth region 20AB may be less than the thermal conductivity of the main-heat-dissipation portion 20A at the third region 20AA, and the heat generated by the display panel 10 at the first region 10A with a large amount of heat may be conducted to the sub-heat dissipation portion 20B more quickly, thereby improving overall heat dissipation efficiency of the module.

It may be understood that the division of the first region 10A and the second region 10B of the display panel 10 in FIG. 16 in one embodiment may be only exemplary and may not represent actual divided regions. During implementation, the first region 10A and the second region 10B may be divided according to actual heat generated by the display panel 10.

Optionally, referring to FIGS. 16 and 18, FIG. 18 illustrates another cross-sectional structural view along the D-D′ direction in FIG. 16. In one embodiment, along the direction Z perpendicular to the plane of the display panel 10, the thickness H1 of the main-heat-dissipation portion 20A at the third region 20AA may be greater than the thickness H2 of the main-heat-dissipation portion 20A at the fourth region 20AB.

In one embodiment, it describes that in order to realize that the thermal conductivity of the main-heat-dissipation portion 20A at the third region 20AA is greater than the thermal conductivity of the main-heat-dissipation portion 20A at the fourth region 20AB, the thickness H1 of the main-heat-dissipation portion 20A in the third region 20AA and the thickness H1 of the main-heat-dissipation portion 20A in the fourth region 20AB may be designed differently. For example, along the direction Z perpendicular to the plane of the display panel 10, the thickness H1 of the main-heat-dissipation portion 20A at the third region 20AA maybe greater than the thickness H2 of the main-heat-dissipation portion 20A at the fourth region 20AB. That is, in the usage of the display panel 10, the heat-dissipation part 20 at the high-heat region may be thickened. Different thicknesses have different thermal conductivity performance. The thicker the thickness H1 of the main-heat-dissipation portion 20A at the third region 20AA is, the higher the thermal conductivity is and the higher the heat dissipation efficiency is. Therefore, by configuring different thicknesses of the main-heat-dissipation portion 20A in different regions, the heat dissipation effect of the display panel 10 in high-heat regions may be improved.

It may be understood that in one embodiment, the main-heat-dissipation portion 20A and the sub-heat-dissipation portion 20B of the heat-dissipation part 20 may be made of a same material. That is, although the third region 20AA and the fourth region 20AB of the main-heat-dissipation portion 20A have different positions and different thermal conductivity, the third region 20AA and the fourth region 20AB may be made of a same material. Entire heat-dissipation part 20 may be made of a same material with high thermal conductivity, which may be beneficial for simplifying the formation process of the heat-dissipation part 20 and improving the process efficiency.

Optionally, when entire heat-dissipation part 20 is made of a same material with high thermal conductivity, in addition to configuring the thickness H1 of the main-heat-dissipation portion 20A at the third region 20AA to be greater than the thickness H2 of the main-heat-dissipation portion 20A at the fourth region 20AB to enhance the thermal conductivity of the main-heat-dissipation portion 20A at the third region 20AA, the material density of the main-heat-dissipation portion 20A at the third region 20AA may be also configured to be greater than the material density of the main-heat-dissipation portion 20A at the fourth region 20AB. For same type of thermally conductive material, the higher the material density is, the better the thermal conductivity is. The main-heat-dissipation portion 20A of the third region 20AA with high density may have higher thermal conductivity and desirable heat dissipation efficiency. Therefore, by configuring different regions of the main-heat-dissipation portion 20A with different material densities, the heat dissipation effect of the display panel 10 in high-heat regions may also be improved.

It may be understood that the material density mentioned in embodiments of the present disclosure may refer to the mass per unit volume of the high thermal-conductivity material used in the main-heat-dissipation portion 20A at a specific volume state. The greater the mass is, the greater the density of the material is. Or in some other optional embodiments, the material density mentioned in embodiments of the present disclosure may also refer to the doping density of the high thermal-conductivity material doped in the main-heat-dissipation portion 20A. At a specific volume state, the greater the mass of the doped high thermal-conductivity material is, the greater the material density is. During implementation, the material density may be selected based on actual application scenario.

It should be noted that in one embodiment, the structure of the main-heat-dissipation portion 20A in different regions may be design differently by changing the structures of different regions of the main-heat-dissipation portion 20A, thereby achieving the effect that the thermal conductivity of the main-heat-dissipation portion 20A at the third region 20AA is greater than the thermal conductivity of the main-heat-dissipation portion 20A at the fourth region 20AB. During implementation, differentiated design manner may include, but may not be limited to above-mentioned manners, and may also be other design manners. Differentiated design manner in one embodiment may be only exemplary, which may not be limited in embodiments of the present disclosure.

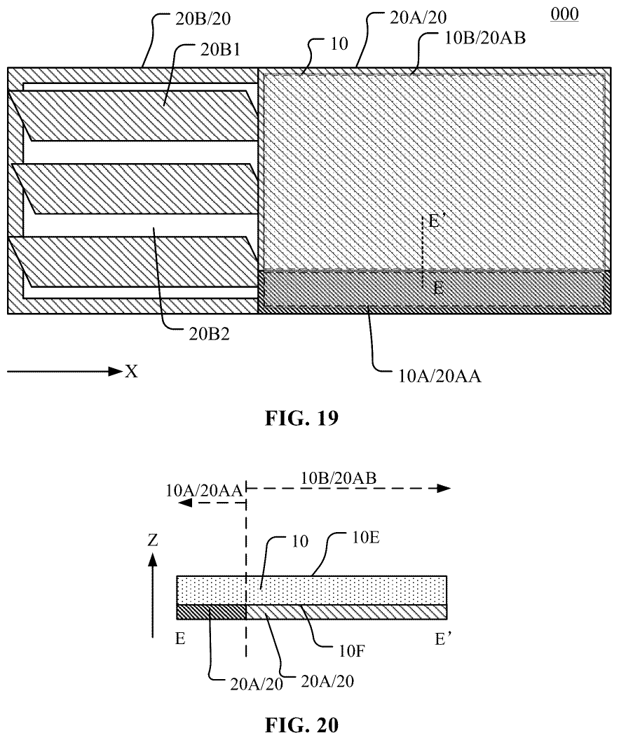

In some optional embodiments, referring to FIGS. 19 and 20, FIG. 19 illustrates another planar structural schematic of a display module according to various embodiments of the present disclosure; and FIG. 20 illustrates a cross-sectional structural view along an E-E′ direction in FIG. 19. In order to clearly illustrate the structure of the display panel 10 and the main-heat-dissipation portion 20A in one embodiment, transparency filling is performed in FIG. 19. In one embodiment, the material of the main-heat-dissipation portion 20A at the third region 20AA may be different from the material of the main-heat-dissipation portion 20A at the fourth region 20AB.

In one embodiment, it describes that in order to realize that the thermal conductivity of the main-heat-dissipation portion 20A at the third region 20AA is greater than that of the main-heat-dissipation portion 20A at the fourth region 20AB, the material of the main-heat-dissipation portion 20A at the third region 20AA and the material of the main-heat-dissipation portion 20A at the fourth region 20AB may be designed differently. For example, the material of the main-heat-dissipation portion 20A at the third region 20AA and the material of the main-heat-dissipation portion 20A at the fourth region 20AB may be different (different filling patterns are used to indicate different materials in drawings). Compared with the material of the main-heat-dissipation portion 20A at the fourth region 20AB, the material selected for the main-heat-dissipation portion 20A at the third region 20AA may have higher thermal conductivity. When actually forming the heat-dissipation part 20, a high thermal-conductivity material may be used to form entire heat-dissipation part 20. Next, the main-heat-dissipation portion 20A corresponding to the display panel 10 at the first region 10A may be hollowed out and filled with the material with higher thermal conductivity to form the main-heat-dissipation portion 20A in the third region 20AA. Furthermore, in the heat-dissipation part 20 finally obtained, the material of the main-heat-dissipation portion 20A at the third region 20AA may be different from the material of the main-heat-dissipation portion 20A at the fourth region 20AB. Moreover, the thermal conductivity of the main-heat-dissipation portion 20A at the third region 20AA may be greater than the thermal conductivity of the main-heat-dissipation portion 20A at the fourth region 20AB. When the heat-dissipation part 20 is used in the display panel 10 to dissipate heat, the heat dissipation effect of the display panel 10 in high-heat regions may be improve.

It may be understood that in order to realize that the thermal conductivity of the main-heat-dissipation portion 20A at the third region 20AA is greater than that of the main-heat-dissipation portion 20A at the fourth region 20AB, that is, when the thermal conductivity of the main-heat-dissipation portion 20A is design differently according to the difference in heat generated in different regions of the display panel 10, the configuration manners in above different embodiments may be selected accordingly. For example, while the main-heat-dissipation portion 20A at the third region 20AA and the main-heat-dissipation portion 20A at the fourth region 20AB are made of different materials, the thickness of the main-heat-dissipation portion 20A at the third region 20AA and the thickness of the main-heat-dissipation portion 20AB of the fourth region 20AB may be further adjusted to be different, which may not be described in detail herein.

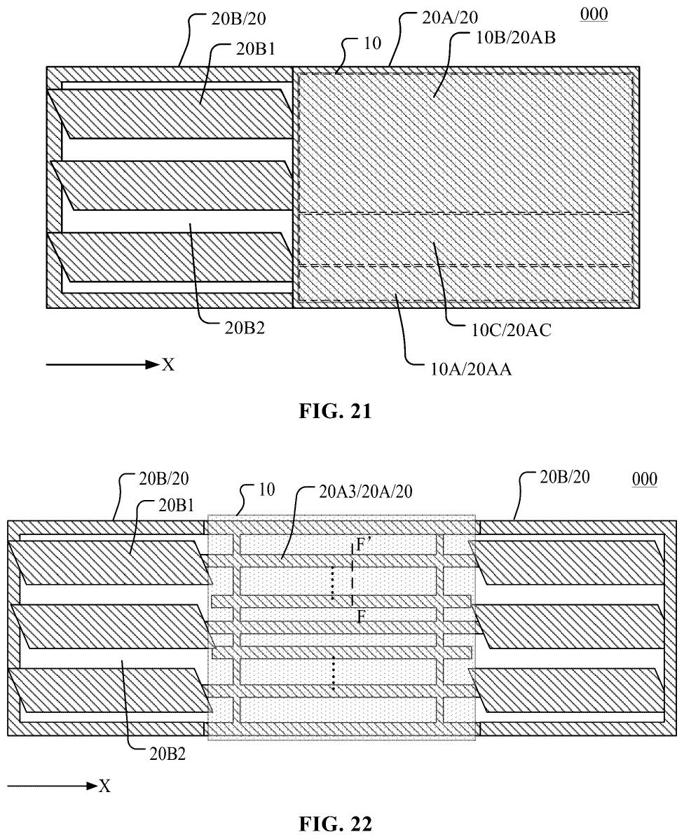

In some optional embodiments, referring to FIG. 21, FIG. 21 illustrates another planar structural schematic of a display module according to various embodiments of the present disclosure. In order to clearly illustrate the structure of the display panel 10 and the main-heat-dissipation portion 20A in one embodiment, transparency is performed in FIG. 21. In one embodiment, the display panel 10 may further include a transition region 10C which may be between the first region 10A and the second region 10B.

The main-heat-dissipation portion 20A may also include the fifth region 20AC. Along the direction Z perpendicular to the plane of the display panel 10, the display panel 10 at the transition region 10C may be overlapped with the main-heat-dissipation portion 20A at the fifth region 20AC.

The thermal conductivity of the main-heat-dissipation portion 20A at the fifth region 20AC may be greater than the thermal conductivity of the main-heat-dissipation portion 20A at the fourth region 20AB. The thermal conductivity of the main-heat-dissipation portion 20A at the fifth region 20AC may be less than the thermal conductivity of the main-heat-dissipation portion 20A at the third region 20AA. It should be noted that, in one embodiment, the thermal conductivity performance of the main-heat-dissipation portion 20A at the fifth region 20AC, the thermal conductivity performance of the main-heat-dissipation portion 20A at the fourth region 20AB, and the thermal conductivity performance of the main-heat-dissipation portion 20A at the third region 20AA may be designed differently through one or more above-mentioned designs such as using different materials, different densities, different thicknesses and the like, which may not be described in detail herein and may refer to above-mentioned embodiments.

In one embodiment, it describes that the main-heat-dissipation portion 20A of the heat-dissipation part 20 may be overlapped with the display panel 10. If the main-heat-dissipation portion 20A covers the region where the display panel 10 is located, the heat dissipation performance of different regions of the main-heat-dissipation portion 20A may be designed differently. The heat generated by the display panel 10 is unevenly distributed when the display panel 10 is used, for example, the position where a driving circuit such as a driving chip and the like is configured for input driving signals may generate relatively high heat with relatively high temperature. Therefore, in embodiments of the present disclosure, different regions of the main-heat-dissipation portion 20A may be designed differently according to the difference in heat generated in different regions of the display panel 10. The main-heat-dissipation portion 20A at the third region 20AA may correspond to the display panel 10 at the first region 10A to dissipate the heat generated by the display panel 10 at the first region 10A; and the main-heat-dissipation portion 20A at the fourth region 20AB may correspond to the display panel 10 at the second region 10B to dissipate the heat generated by the display panel 10 at the second region 10B. The thermal conductivity of the main-heat-dissipation portion 20A at the third region 20AA may be configured to be greater than the thermal conductivity of the main-heat-dissipation portion 20A at the fourth region 20AB. The heat dissipation speed and heat dissipation efficiency of the main-heat-dissipation portion 20A at the third region 20AA to the display panel 10 at the first region 10A may be improved; and the heat generated by the display panel 10 at the first region 10A, which has a large amount of heat, may be conducted to the blade structure 20B1 of the heat-dissipation part 20B as quickly as possible. Furthermore, the blade structure 20B1 may dissipate heat faster and more effectively, thereby improving the heat dissipation effect of the module. In order to avoid uneven heat dissipation due to sudden changes in heat intensity when heat is conducted between the main-heat-dissipation portion 20A at the third region 20AA and the main-heat-dissipation portion 20A at the fourth region 20AB, the display panel 10 may further include the transition region 10C between the first region 10A and the second region 10B. Similarly, along the direction Z perpendicular to the plane of the display panel 10, the display panel 10 at the transition region 10C may be overlapped with the main-heat-dissipation portion 20A at the fifth region 20AC. The main-heat-dissipation portion 20A at the fifth region 20AC may correspond to the display panel 10 at the transition region 10C to dissipate the heat generated by the display panel 10 at the transition region 10C. The thermal conductivity of the main-heat-dissipation portion 20A at the fifth region 20AC may be configured to be between the thermal conductivity of the main-heat-dissipation portion 20A at the third region 20AA and the thermal conductivity of the main-heat-dissipation portion 20A at the fourth region 20AB. The main-heat-dissipation portion 20A at the fifth region 20AC may be configured as transition during heat conduction, which may be beneficial for matching the heat distribution of entire main-heat-dissipation portion 20A and making the heat dissipation effect of the heat-dissipation part 20 more uniform.

It may be understood that the division of the first region 10A, the transition region 10C, and the second region 10B of the display panel 10 in FIG. 21 in one embodiment may be only exemplary and may not represent actual divided regions. During implementation, the first region 10A, the transition region 10C, and the second region 10B may be divided according to actual heat generated by the display panel 10.

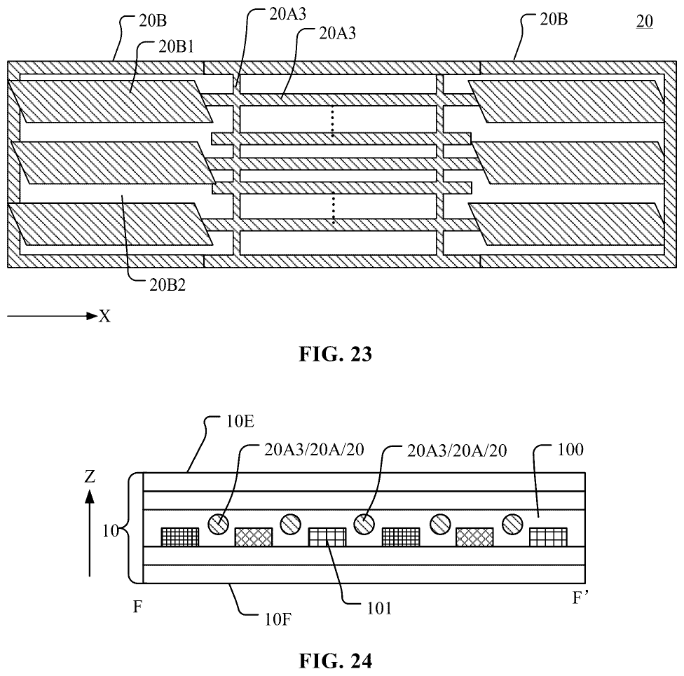

In some optional embodiments, referring to FIGS. 22-24, FIG. 22 illustrates another planar structural schematic of a display module according to various embodiments of the present disclosure; FIG. 23 illustrates a planar structural schematic of a heat-dissipation part after being separated from the display panel in FIG. 22; and FIG. 24 illustrates a cross-sectional structural view along an F-F′ direction in FIG. 22. In order to clearly illustrate the structure of the display panel 10 and the main-heat-dissipation portion 20A in one embodiment, transparency filling is performed in FIG. 22. In one embodiment, the main-heat-dissipation portion 20A of the heat-dissipation part 20 may include a heat-conducting strip 20A3; and the heat-conducting strip 20A3 may be inside the display panel 10 and connected to the sub-heat-dissipation portion 20B.

In one embodiment, it describes that the heat-dissipation part 20 may include the main-heat-dissipation portion 20A; and along the direction Z perpendicular to the plane of the display panel 10, the main-heat-dissipation portion 20A may be at least partially overlapped with the display panel 10. The main-heat-dissipation portion 20A may also be a structure of the heat-conducting strip 20A3 inside the display panel 10. Being inside the display panel 10 may be understood as that the heat-conducting strip 20A3 may be in one or more film layers of the display panel 10. It may be understood that the heat-conducting strip 20A3 disposed inside the display panel 10 may be configured as the main-heat-dissipation portion 20A, and the number of the heat-conducting strips 20A3 included in the display panel 10 may not be limited. During implementation, the number of the heat-conducting strips 20A3 may be designed according to available space inside the display panel 10. In one embodiment, the number of the heat-conducting strips 20A3 may be only exemplary, which only needs to satisfy that original functions of the display panel 10 (such as the display function and internal circuit driving function) may not be affected.

The heat-conducting strip 20A3 in one embodiment may be inside the display panel 10 and connected to the sub-heat-dissipation portion 20B. The heat-conducting strip 20A3 may be in an elongated shape and disposed in the film layer of the display panel 10, which may ensure that the heat-conducting strip 20A3 occupies less space as possible in the film layer and also ensure that the heat is conducted from the heat-conducting strip 20A3 to the blade structure 20B1 of the sub-heat-dissipation portion 20B. The main-heat-dissipation portion 20A with the structure of the heat-conducting strip 20A3 may conduct and dissipate the heat generated inside the display panel 10. Finally, the heat may be dissipated through the hollow region formed at the blade structure 20B1 of the sub-heat-dissipation portion 20B, thereby achieving rapid heat dissipation effect of the heat-dissipation part 20 on the display panel 10. In addition, the main-heat-dissipation portion 20A may be disposed inside the display panel 10, which also be beneficial for reducing the space of entire module occupied by the heat-dissipation part 20 and making overall structure of the module simpler.

It may be understood that the shape and the number of the heat-conducting strips 20A3 inside the display panel 10 illustrated in one embodiment may be only exemplary. During implementation, the display module may include multiple heat-conducting strips 20A3 which may be interconnected structures having different extending directions; and finally all heat-conducting strips 20A3 may be connected to the blade structures 20B1 of the sub-heat-dissipation portion 20B.

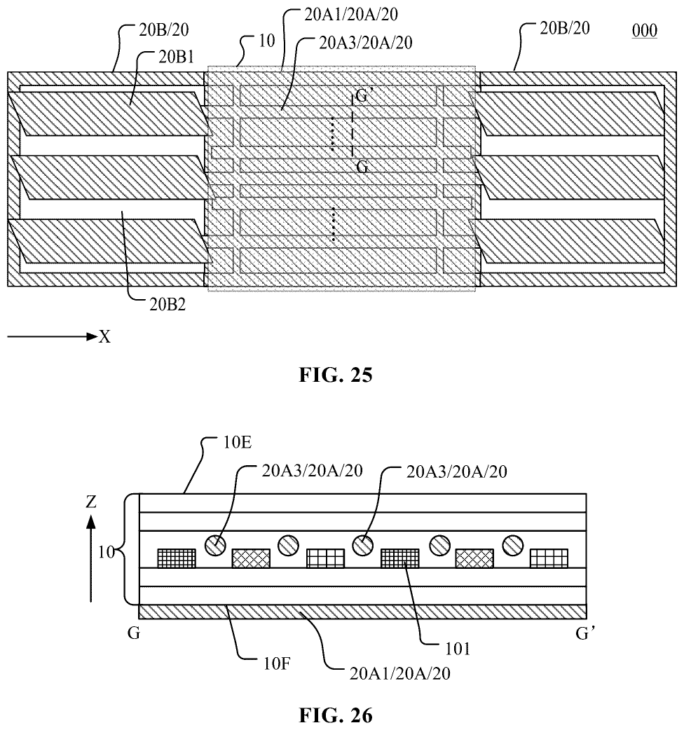

Optionally, referring to FIGS. 25-26, FIG. 25 illustrates another planar structural schematic of a display module according to various embodiments of the present disclosure; and FIG. 26 illustrates a cross-sectional structural view along a G-G′ direction in FIG. 25. In order to clearly illustrate the structure of the display panel 10 and the main-heat-dissipation portion 20A in one embodiment, transparency filling is performed in FIG. 25. The main-heat-dissipation portion 20A in one embodiment may include the heat-conducting strip 20A3 inside the display panel 10 and also include the first main-heat-dissipation portion 20A1 on the side of the backlight surface 10F of the display panel 10. The first main-heat-dissipation portion 20A1 may be a structure covering the display panel 10. That is, the heat-conducting strip 20A3 inside the display panel 10 and the first main-heat-dissipation portion 20A1 on the side of the backlight surface 10F of the display panel 10 may together form the main-heat-dissipation portion 20A of the heat-dissipation part 20. The heat-conducting strip 20A3 may conduct the heat generated inside the display panel 10, and the first main-heat-dissipation portion 20A1 may conduct the heat of entire display panel 10. The heat-conducting strip 20A3 and the first main-heat-dissipation portion 20A1 may together conduct the heat to the sub-heat-dissipation portion 10B on the periphery of the display panel 10, which may be beneficial for improving the heat dissipation efficiency and the heat dissipation effect.

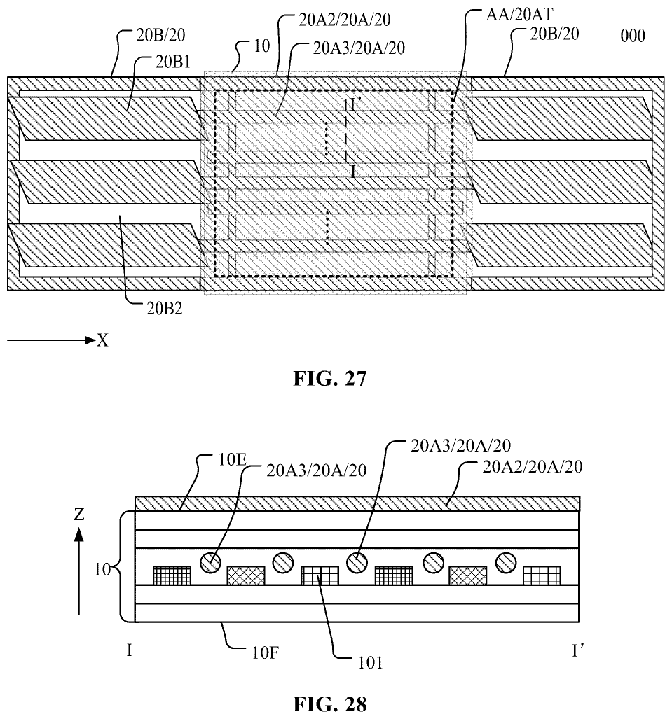

Optionally, referring to FIGS. 27 and 28, FIG. 27 illustrates another planar structural schematic of a display module according to various embodiments of the present disclosure; and FIG. 28 illustrates a cross-sectional structural view along an I-I′ direction in FIG. 27. In order to clearly illustrate the structure of the display panel 10 and the main-heat-dissipation portion 20A in one embodiment, transparency filling is performed in FIG. 27. The main-heat-dissipation portion 20A in one embodiment may include the heat-conducting strip 20A3 inside the display panel 10 and may also include the second main-heat-dissipation portion 20A2 on the side of the light-exiting surface 10E of the display panel 10. The second main-heat-dissipation portion 20A2 may be a structure covering the display panel 10. The second main-heat-dissipation portion 20A2 may include the light-transmitting region 20AT, and the second main-heat-dissipation portion 20A2 at the light-transmitting region 20AT may be transparent. In addition, along the direction Z perpendicular to the plane of the display panel 10, the second main-heat dissipation portion 20A2 at the light-transmitting region 20AT may be overlapped with the display region AA of the display panel 10. That is, the heat-conducting strip 20A3 inside the display panel 10 and the second main-heat-dissipation portion 20A2 on the side of the light-exiting surface 10E of the display panel 10 may together form the main-heat-dissipation portion 20A of the heat-dissipation part 20. The heat-conducting strip 20A3 may conduct the heat generated inside the display panel 10, and the second main-heat-dissipation portion 20A2 may conduct the heat of entire display panel 10. The heat-conducting strip 20A3 and the second main-heat-dissipation portion 20A2 may together conduct the heat to the sub-heat-dissipation portion 10B on the periphery of the display panel 10, which may be beneficial for improving the heat dissipation efficiency and the heat dissipation effect.

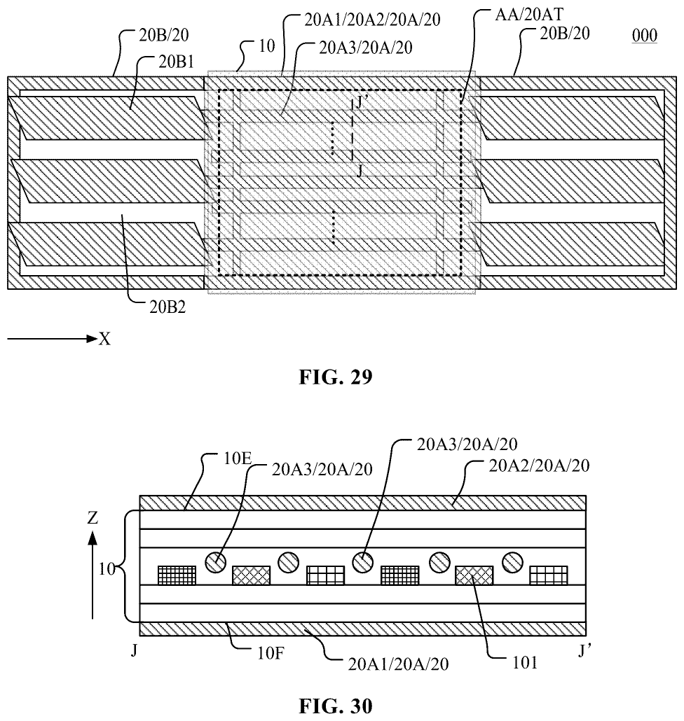

Optionally, referring to FIGS. 29 and 30, FIG. 29 illustrates another planar structural schematic of a display module according to various embodiments of the present disclosure; and FIG. 30 illustrates a cross-sectional structural view along a J-J′ direction in FIG. 29. In order to clearly illustrate the structure of the display panel 10 and the main-heat-dissipation portion 20A in one embodiment, transparency filling is performed in FIG. 29. The main-heat-dissipation portion 20A in one embodiment may not only include the heat-conducting strip 20A3 inside the display panel 10 and also include the first main-heat-dissipation portion 20A1 on the side of the backlight surface 10F of the display panel 10, and the second main-heat-dissipation portion 20A2 on the light-exiting surface 10E side of the display panel 10. The first main-heat-dissipation portion 20A1 and the second main-heat-dissipation portion 20A2 may each be a structure covering the display panel 10. The second main-heat-dissipation portion 20A2 may include the light-transmitting region 20AT, and the second main-heat-dissipation portion 20A2 at the light-transmitting region 20AT may be transparent. In addition, along the direction Z perpendicular to the plane of the display panel 10, the second main-heat dissipation portion 20A2 at the light-transmitting region 20AT may be overlapped with the display region AA of the display panel 10. That is, the heat-conducting strip 20A3 inside the display panel 10, the first main-heat-dissipation portion 20A1 on the side of the backlight surface 10F of the display panel 10, and the second main-heat-dissipation portion 20A2 on the side of the light-exiting surface 10E of the display panel 10 may together form the main-heat-dissipation portion 20A of the heat-dissipation part 20. The heat-conducting strip 20A3 may conduct the heat generated inside the display panel 10; and the first main-heat-dissipation portion 20A1 and the second main-heat-dissipation portion 20A2 may conduct the heat of entire display panel 10. The heat-conducting strip 20A3, the first main-heat-dissipation portion 20A1 and the second main-heat-dissipation portion 20A2 may together conduct the heat to the sub-heat-dissipation portion 10B on the periphery of the display panel 10, which may be beneficial for more effectively increasing the heat dissipation speed, improving the heat dissipation efficiency and desirably improving the heat dissipation effect.

It may be understood that in FIG. 24 of above-mentioned embodiment, the cross-sectional shape of the heat-conducting strip 20A3 may be circular as an example for illustration. During implementation, the cross-sectional shape of the heat-conducting strip 20A3 may include, but may not be limited to, such circular shape, and may also include other shapes, which may not be described in detail herein. The cross-sectional shape of the heat-conducting strip 20A3 only needs to satisfy that the heat-conducting strip may be inside the display panel and connected to the sub-heat-dissipation portion and may not affect normal display. The film structure of the display panel 10 in FIG. 24 may be only exemplary. During implementation, the film layer structure of the display panel 10 may be exemplarily designed according to the type of the display panel 10, which only needs to satisfy that the heat-conducting strip 20A3 may be inside the display panel 10.

Optionally, as shown in FIGS. 22-24, in one embodiment, the display panel 10 may include a plurality of light-emitting elements 101; and the orthographic projection of the heat-conducting strip 20A3 on the plane of the display panel 10 may not be overlapped with the orthographic projection of the light-emitting element 101 on the plane of the display panel 10.

In one embodiment, it describes that the display panel 10 may include the plurality of light-emitting elements 101 for light emission. It may be understood that when the display panel 10 is a self-light-emitting display panel, such as an organic light-emitting diode display panel or a micro-light-emitting diode display panel or other self-light-emitting display panels, the light-emitting element 101 may be understood as a light-emitting diode (such as an organic light-emitting diode, a micro-light-emitting diode, a sub-millimeter light-emitting diode or the like) disposed inside the display panel 10 and driven to emit light by a driving circuit. As shown in FIG. 24, different filling patterns may represent different light-emitting colors. Optionally, the display panel 10 may be a self-light-emitting display panel. When the light-emitting element 101 is an organic light-emitting diode, the film layer structure of the display panel may include a pixel definition layer. The organic light-emitting diode may be disposed in the opening formed in the pixel definition layer. The orthographic projection of the heat-conducting strip 20A3 on the plane of the display panel 10 may not be overlapped with the orthographic projection of the light-emitting element 101 on the plane of the display panel 10. It may be understood that the orthographic projection of the heat-conducting strip 20A3 on the plane of the display panel 10 may not be overlapped with the orthographic projection of the opening formed in the pixel definition layer on the plane of the display panel 10. When the display panel 10 is a passive light-emitting display panel (such as a liquid crystal display panel), the light-emitting element 101 may be understood as a light-emitting opening region (not shown in drawings) of single sub-pixel. Optionally, the display panel 10 may be a passive light-emitting display panel. The film layer structure of the display panel 10 may include a black matrix layer.

The black matrix layer may be configured with light-emitting opening regions for multiple sub-pixels. The orthographic projection of the heat-conducting strip 20A3 on the plane of the display panel 10 may not be overlapped with the orthographic projection of the light-emitting element 101 on the plane of the display panel 10. It may be understood that the orthographic projection of the heat-conducting strip 20A3 on the plane of the display panel 10 may not be overlapped with the orthographic projection of the light-emitting opening region formed in the black matrix layer on the plane of the display panel 10. In one embodiment, the orthographic projection of the heat-conducting strip 20A3 on the plane of the display panel 10 and the orthographic projection of the light-emitting element 101 on the plane of the display panel 10 may be configured to be not overlapped with each other, which may ensure that when the heat-conducting strip 20A3 is disposed inside the display panel 10, the position of the light-emitting element 101 may be avoided. Furthermore, the heat-conducting strip 20A3 may be prevented from affecting normal light-emitting display effect of the display panel 10, which may be beneficial for achieving the heat dissipation effect while ensuring the display quality.

Optionally, as shown in FIGS. 22-24, in one embodiment, the display panel 10 may include at least one insulating layer 100, and the heat-conducting strip 20A3 may be embedded in the insulating layer 100.

In one embodiment, it describes that the heat-dissipation part 20 may include the main-heat-dissipation portion 20A; and when the main-heat-dissipation portion 20A is at least partially overlapped with the display panel 10 along the direction Z perpendicular to the plane of the display panel 10, the main-heat-dissipation portion 20A may be a structure of the heat-conducting strip 20A3 inside the display panel 10. At this point, the heat-conducting strip 20A3 may be disposed in a certain film layer in the display panel 10. Optionally, the display panel 10 may include at least one insulating layer 100, and the heat-conducting strip 20A3 may be embedded in the insulating layer 100. By disposing the heat-conducting strip in the insulating layer 100, the heat-conducting strips 20A3 may avoid the conductive layer in the display panel 10, which may avoid the configuration of the heat-conducting strips 20A3 from affecting the use of functional layers (such as the conductive layer) in the display panel 10, which may further ensure the display quality while dissipating heat.

Optionally, in the film structure of the display panel 10, the film thickness of the insulating layer, such as the protective layer for protecting the conductive structure or the planarizing layer for planarization, may be relatively thick. Therefore, disposing the heat-conducting strips 20A3 in the insulating layers 100 with relatively thick film layer may improve the thermal conductivity efficiency of the heat-conducting strip 20A3. The thermal conductivity efficiency may be affected by the cross-sectional area of the heat-conducting strip 20A3. When the heat-conducting strip 20A3 is disposed in an insulating layer 100, the heat-conducting strip 20A3 may be set as thick as possible to increase the heat dissipation efficiency of the heat-conducting strip 20A3 as the main-heat-dissipation portion 20A as possible.

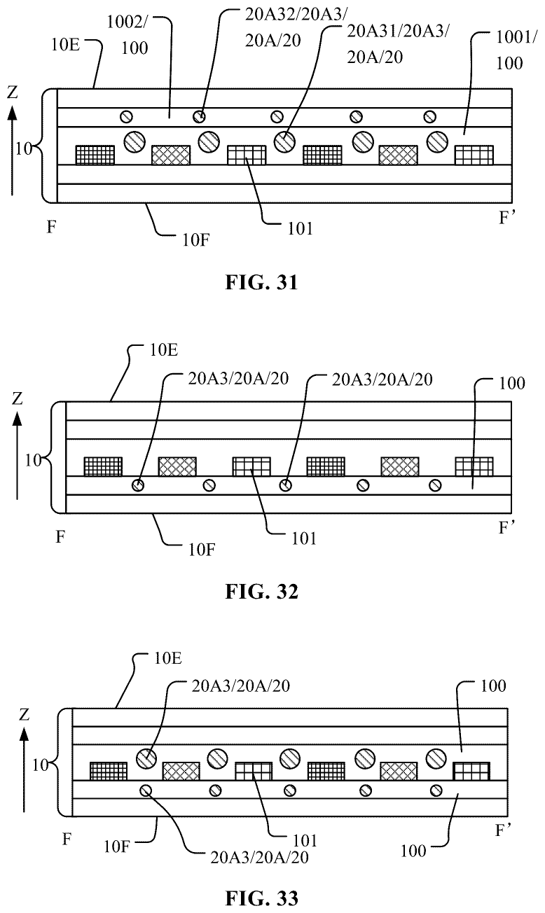

In some optional embodiments, referring to FIGS. 22 and 31, FIG. 31 illustrates another cross-sectional structural view along the F-F′ direction in FIG. 22. In one embodiment, the heat-conducting strips 20A3 may include the first heat-conducting strip 20A31 and the second heat-conducting strip 20A32. The first heat-conducting strip 20A31 and the second heat-conducting strip 20A32 may be in different film layers of the display panel 10.

In one embodiment, it describes that when the main-heat-dissipation portion 20A included in the heat-dissipation part 20 is configured as the heat-conducting strips 20A3 inside the display panel 10, the heat-conducting strips 20A3 may include the first heat-conducting strip 20A31 and the second heat-conducting strip 20A32 in different film layers of the display panel 10. Optionally, the display panel 10 may at least include the first insulating layer 1001 and the second insulating layer 1002. The first heat-conducting strip 20A31 may be embedded in the first insulating layer 1001, and the second heat-conducting strip 20A32 may be embedded in the second insulating layer 1002. In such way, the heat-conducting strips 20A3 may be disposed in multiple film layers. In each insulating layer of the film structure of the display panel 10, the heat-conducting strip 20A3 may be disposed at a position that only has extra space and does not affect normal display. Therefore, the contact area between the main-heat-dissipation portion 20A and the display panel 10 may be as large as possible, which may be beneficial for improving the heat dissipation efficiency of the main-heat-dissipation portion 20A.

It may be understood that in one embodiment, the first heat-conducting strip 20A31 may be embedded in the first insulating layer 1001, and the second heat-conducting strip 20A32 may be embedded in the second insulating layer 1002. The positions of the first insulating layer 1001 and the second insulating layer 1002 inside the display panel 10 in FIG. 31 may be only exemplary. During implementation, the first insulating layer 1001 and the second insulating layer 1002 may be any two different insulating layers in the film layer structure of the display panel 10.

It should be noted that in one embodiment, along the direction Z perpendicular to the plane of the display panel 10, the first heat-conducting strip 20A31 and the second heat-conducting strip 20A32 may be at different insulating layers. However, the first heat-conducting strip 20A31 and the second heat-conducting strip 20A32 may be overlapped with each other if space allows, thereby reducing the space occupied by the heat-conducting strip inside the display panel 10; or the first heat-conducting strip 20A31 and the second heat-conducting strip 20A32 may not be overlapped with each other, thereby increasing the heat dissipation area of overall heat-conducting strips and improving the heat dissipation effect, which may not be limited in one embodiment. During implementation, the first heat-conducting strip 20A31 and the second heat-conducting strip 20A32 may be selected according to actual need. The first heat-conducting strip 20A31 and the second heat-conducting strip 20A32 may also be at different insulating layers, but two corresponding orthographic projections on the plane of the display panel 10 may be intersecting structures, which only needs to satisfy that the configuration of the first heat conducting strip 20A31 and the second heat conducting strip 20A32 may not affect normal light-emitting display of the display panel 10.

It should be further explained that the cross-sectional shapes of the first heat-conducting strip 20A31 and the second heat-conducting strip 20A32 in one embodiment may be same or different; and the cross-sectional areas of the first heat-conducting strip 20A31 and the second heat-conducting strip 20A32 may be same or different. During implementation, the cross-sectional shapes and the cross-sectional areas may be configured according to the thicknesses and configuration ranges of corresponding insulating layers, which only needs to satisfy that the configuration of the first heat conducting strip 20A31 and the second heat conducting strip 20A32 may not affect normal light-emitting display of the display panel 10.

Optionally, as shown in FIGS. 22-24, in one embodiment, the heat-conducting strip 20A3 may be a solid structure. When the main-heat-dissipation portion 20A included in the heat-dissipation part 20 is configured as the heat-conducting strip 20A3 inside the display panel 10, the heat-conducting strip 20A3 may be a solid structure to adapt to the thickness of the film layer in the display panel 10. The thin-long and solid-structured heat-conducting strip 20A3 may be firmly embedded in the insulating layer of the display panel 10 to prevent the thickness of the insulating layer from affecting the outer diameter of the heat-conducting strip 20A3, which may be beneficial for ensuring the stability and reliability of the main-heat-dissipation portion 20A inside the display panel 10.

Optionally, when an insulating layer included in the plurality of insulating layers 100 of the display panel 10 is relatively thick, the heat-conducting strip 20A3 with an internal hollow structure may be embedded in the insulating layer (not shown in drawings) with relatively large thickness. At this point, the internal hollow structure included in the heat-conducting strip 20A3 and the internal hollow structure included in the blade structure 20B1 may be connected to communicate with each other and may be disposed with liquid or gas. By forming the hollow interior and adding gas, the gas in the closed space may form convection to increase the heat conduction speed of the heat-dissipation part 20, and further improve the heat dissipation effect of the display panel 10.

Optionally, the heat-conducting strip 20A3 in one embodiment may include a light-blocking material. In one embodiment, it describes that the heat-conducting strip 20A3 may be made of a material not only with high thermal conductivity, but also with both high thermal conductivity and light blocking. When along the direction Z perpendicular to the plane of the display panel 10, the position of the film layer where the heat-conducting strip 20A3 is located is on the side of the light-emitting element 101 facing the light-exiting surface 10E of the display panel 10 or when the position of the film layer where the heat-conducting strip 20A3 is located is at a same layer and same height as the light-emitting element 101, in order to prevent the heat-conducting strip 20A3 from affecting normal light emission of the light-emitting element 101, the configuration of the heat-conducting strip 20A3 may need to avoid the light-emitting element 101 inside the display panel 10. It may be understood that the orthographic projection of at least a part of the heat-conducting strips 20A3 on the plane of the display panel 10 must be between the orthographic projections of two adjacent light-emitting elements 101 on the plane of the display panel 10. Therefore, in one embodiment, the heat-conducting strip 20A3 may be configured to include the light-blocking material, which may prevent color crosstalk between two light-emitting elements 101, thereby being beneficial for achieving the heat dissipation effect and improving the display quality. When along the direction Z perpendicular to the plane of the display panel 10, the position of the film layer where the heat-conducting strip 20A3 is located is on the side of the light-emitting element 101 away from the light-exiting surface 10E of the display panel 10, the heat-conducting strip 20A3 may be configured to include the light-blocking material. In addition, when the orthographic projection of at least a part of the heat-conducting strips 20A3 on the plane of the display panel 10 is between the orthographic projections of two adjacent light-emitting elements 101 on the plane of the display panel 10, if the film layer on the side of the light-emitting element 101 away from the light-exiting surface 10E of the display panel 10 includes an active layer, the heat-conducting strips 20A3 may effectively block the light from the light-emitting element 101 reaching the active layer, thereby preventing the light from affecting the performance of the active layer. The heat-conducting strip 20A3 in one embodiment may be configured to include the light-blocking material. In such way, there is no need to dispose an additional light-blocking layer in the film layer structure of the display panel 10, which may reduce the number of film layers on the panel and be beneficial for achieving the thin and light panel design.

Furthermore, optionally, referring to FIGS. 22, 24, 32 and 33, FIG. 32 illustrates another cross-sectional structural view along the F-F′ direction in FIG. 22; and FIG. 33 illustrates another cross-sectional structural view along the F-F′ direction in FIG. 22. When the heat-conducting strip 20A3 includes the light-blocking material, the film layer where the heat-conducting strip 20A3 is located may be above the layer where the light-emitting element 101 is located (the upper side as shown in FIG. 24). That is, the film layer where the heat-conducting strip 20A3 is located may be on the side of the layer of the light-emitting element 101 facing the light-exiting surface 10E of the display panel 10 (as shown in FIG. 24). Or the film layer where the heat-conducting strip 20A3 is located may be below the layer where the light-emitting element 101 is located (the lower side as shown in FIG. 32). That is, the film layer where the heat-conducting strip 20A3 is located may be on the side of the layer of the light-emitting element 101 away from the light-exiting surface 10E of the display panel 10. For example, for the micro-light-emitting diode display panel, the light-emitting direction of the micro-light-emitting diode may be 360°. Therefore, the film layer of the heat-conducting strip 20A3 with light-blocking function may be disposed on the side of the layer of the light-emitting element 101 away from the light-exiting surface 10E of the display panel 10, which may block the light emitted from the lower side of the light-emitting element 101 of the micro-light-emitting diode (as shown in FIG. 32). Or when the heat-conducting strips 20A3 are at different film layers, the film layer of a part of the heat-conducting strips 20A3 may be above the layer of the light-emitting element 101; that is, the film layer of a part of the heat-conducting strips 20A3 may be on the side of the layer of the light-emitting element 101 facing the light-exiting surface 10E of the display panel 10. The film layer of a part of the heat-conducting strips 20A3 may be below the layer of the light-emitting element 101; that is, the film layer of a part of the heat-conducting strips 20A3 may be on the side of the layer of the light-emitting element 101 away from the light-exiting surface 10E of the display panel 10 (as shown in FIG. 33). The heat-conducting strips 20A3 on the upper and lower sides of the light-emitting element 101 and at different film layers may together achieve the effect of blocking light and preventing color crosstalk.

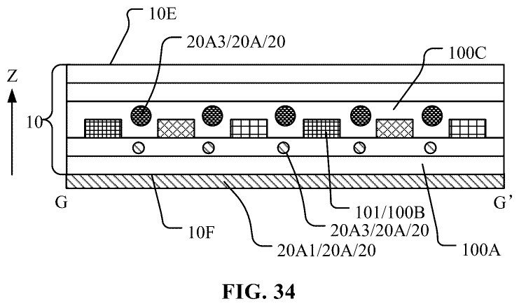

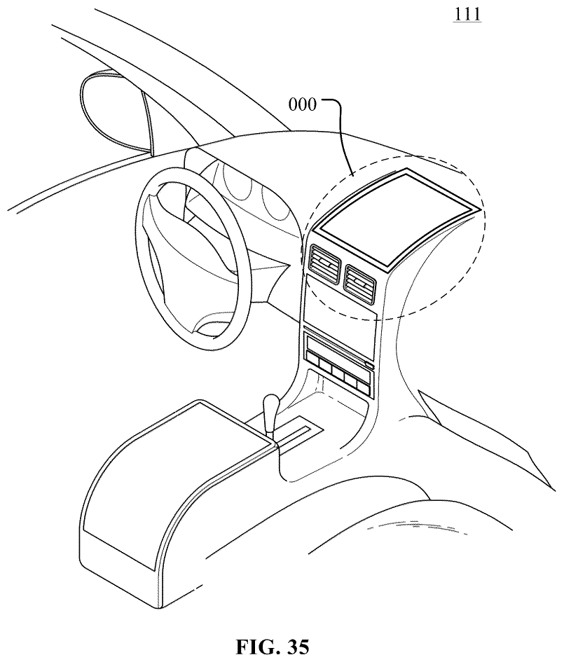

In some optional embodiments, referring to FIGS. 25 and 34, FIG. 34 illustrates another cross-sectional structural view along the G-G′ direction in FIG. 25. In the film layer structure of the display panel 10 provided in one embodiment, the display panel 10 may at least include a substrate 100A, a light-emitting-element layer 100B, and a first protective layer 100C. The first protective layer 100C may be on the side of the light-emitting-element layer 100B away from the substrate 100A; and the light-emitting element 101 may be at the light-emitting-element layer 100B. At least a part of the heat-conducting strips 20A3 may be at the first protective layer 100C, and the heat-conducting strip 20A3 at the first protective layer 100C may include the light-blocking material.

In one embodiment, it describes that an optional film layer structure of the display panel 10 may at least include the substrate 100A, the light-emitting-element layer 100B, and the first protective layer 100C. The light-emitting element 101 may be at the light-emitting-element layer 100B, the first protective layer 100C may be on the side of the light-emitting-element layer 100B away from the substrate 100A, and the first protective layer 100C may at least cover the plurality of light-emitting elements 101, which may provide planarization for the film layer while protecting the light-emitting elements 101. When the main-heat-dissipation portion 20A of the heat-dissipation part 20 includes the structure of the heat-conducting strip 20A3, the film thickness of the first protective layer 100C may be relatively thick in order to ensure protective effect and planarization effect. Therefore, at least a part of the heat-conducting strips 20A3 may be in the first protective layer 100C, which may make the heat-conducting strips 20A3 embedded in the first protective layer 100C as thick as possible, thereby being beneficial for improving the heat conduction efficiency. When at least a part of the heat-conducting strips 20A3 is at the first protective layer 100C, original film layers of the display panel may be reused in the formation of the heat-conducting strips 20A3, which may be beneficial for thin panel design. The first protective layer 100C may be on the side of the light-emitting-element layer 100B away from the substrate 100A, that is, the first protective layer 100C may be on the side of the light-emitting-element layer 100B adjacent to the light-exiting surface 10E of the display panel 10. Therefore, the heat-conducting strip 20A3 at the first protective layer 100C may include the light-blocking material. That is, among the heat-conducting strips 20A3 included in the main-heat-dissipation portion 20A, the heat-conducting strips 20A3 at the first protective layer 100C may be made of a high thermal-conductivity and light-blocking material, which may not only ensure the heat dissipation effect but also block large viewing-angle light emitted from the light-emitting element 101, thereby preventing color crosstalk and improving display quality.

Optionally, when the heat-conducting strips 20A3 in one embodiment are disposed in the internal structure of the display panel 10, the arrangement density of the heat-conducting strips 20A3 in different regions (the arrangement density may be understood as the number of heat-conducting strips 20A3 arranged in a unit region) may be different. For example, in regions with high generated heat when the display panel 10 is used, the arrangement density of the heat-conducting strips 20A3 may be higher; or in regions with high generated heat when the display panel 10 is used, the number of layers of the heat-conducting strips 20A3 may be higher compared with regions with low generated heat; or the arrangement density may be configured using other differentiated design manners, which may not be described in detail herein.

It may be understood that in one embodiment, in the heat-conducting strips 20A3 included in the main-heat-dissipation portion 20A, it only needs to ensure that the heat-conducting strip 20A3 at the first protective layer 100C may include the light-blocking material (relatively dense filling pattern is used to indicate the light-blocking material in FIG. 34). The heat-conducting strips in some insulating layers on the side of the light-emitting-element layer 100B adjacent to the substrate 100A may be made of a light-blocking material or a non-light-blocking material, which may not be limited in one embodiment.

In some optional embodiments, referring to FIG. 35, FIG. 35 illustrates a partial structural schematic of a vehicle terminal according to various embodiments of the present disclosure. A vehicle terminal 111 provided in one embodiment may include the display module 000 provided in above-mentioned embodiments of the present disclosure.

In one embodiment, the vehicle terminal 111 may include the display module 000 provided in above-mentioned embodiment. With the transportation development, vehicles become an important part of human transportation. Display devices, as the focus of human-computer interaction, may play an increasingly important role in smart vehicles. However, as users have higher requirement for the quality of in-vehicle displays, the heat dissipation problem of in-vehicle display modules has also become one important factor that affects users' choice of vehicle terminals. In the existing technology, a special heat dissipation system for the vehicle display screen is disposed. For example, the structures including a cooling chassis and a cooling fan may be installed behind the vehicle display screen, which may have high cost and complex structure, but also occupy relatively large space, affect the layout of the central control region of the vehicle and affect the design of the vehicle itself. In order to solve above problem, the display module 000 provided in above-mentioned embodiment may be disposed in the vehicle terminal 111 in one embodiment. The design of the heat-dissipation part 20 may not only have simple structure which can effectively control the space occupied by entire display module 000 and may also ensure the heat dissipation effect without affecting the layout of the central control region of the vehicle and the design of the vehicle itself.

It may be understood that the vehicle terminal 111 provided by embodiments of the present disclosure may not only include the display module 000 but may also include other structures such as a control system, which may not be limited in the present disclosure. The vehicle terminal 111 provided by embodiments of the present disclosure may have the beneficial effects of the display module 000 provided by embodiments of the present disclosure, which may refer to specific description of the display module 000 in above-mentioned embodiments and may not be described in detail herein.

It may be understood that FIG. 35 in one embodiment may only exemplarily illustrate the configuration position and placement direction of the display module 000 in the vehicle terminal 111. During implementation, the configuration position of the display module 000 may also be other positions in the central control region of the vehicle. The sub-heat dissipation portion 20B of the heat-dissipation part 20 in the display module 000 may also be at other peripheral positions of the display panel 10, which is exemplarily shown in FIG. 35. In some other optional embodiments, the display module 000 may also be a flexible display module, that is, the display panel 10 may be a flexible display panel. The heat-dissipation part 20 may also be configured to be bent to follow the shape of the flexible display panel, and the sub-heat dissipation portion 20B may also be a curved structure, which only needs to satisfy that the display module 000 may be matched and installed with the internal structure of the vehicle terminal 111.

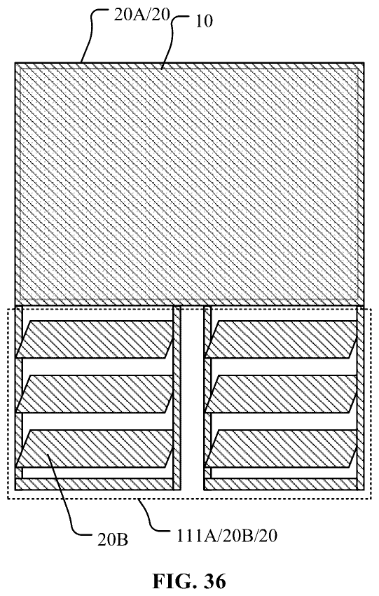

In some optional embodiments, referring to FIGS. 35 and 36, FIG. 36 illustrates a partial structural schematic of a central control region of the vehicle terminal in FIG. 35. In one embodiment, the vehicle terminal 111 may also include an air-conditioning outlet 111A; and the sub-heat-dissipation portion 20B may be reused as the air-conditioning outlet 111A.

In one embodiment, it describes that when the display module 000 is applied to the vehicle terminal 111, the vehicle terminal 111 may include the air-conditioning outlet 111A, the air-conditioning outlet 111A may be used to blow air when the air-conditioning function is turned on. Therefore, when the display module 000 in one embodiment is installed inside the vehicle terminal 111, the sub-heat dissipation portion 20B of the heat-dissipation part 20 may be reused as the air conditioning outlet 111A. That is, the air-conditioning outlet 111A included in the vehicle terminal 111 itself may be used as the sub-heat-dissipation portion 20B of the heat-dissipation part 20, which may not only simplify overall structure of the vehicle terminal 111, but also satisfy the heat conduction when the display panel 10 in the display module 000 is used. Furthermore, the air blower of the air-conditioning may further be used to quickly dissipate the heat conducted on the blade structure 20B1 of the sub-heat-dissipation portion 20B, which may be further beneficial for improving the heat dissipation efficiency of the display module 000 in the vehicle terminal 111 and ensuring product service life.

It may be seen from above-mentioned embodiments that the display module and the vehicle terminal provided by the present disclosure may at least achieve following beneficial effects.

The display module of the present disclosure may include the display panel and the heat-dissipation part; and the heat-dissipation part may at least include the main-heat-dissipation portion and the sub-heat-dissipation portion. by configuring that the main-heat-dissipation portion is at least partially overlapped with the display panel along the direction perpendicular to the plane of the display panel, the heat generated when the display panel is used may be conducted through the main-heat-dissipation portion of the heat-dissipation part. In addition, along the direction in parallel with the plane of the display panel, the sub-heat-dissipation portion included in the heat-dissipation part may be at least on one side of the main-heat-dissipation portion. After the heat generated in the usage of the display panel 10 is conducted and dissipated by the main-heat-dissipation portion, the heat may be further conducted to the sub-heat-dissipation portion in the peripheral region of the display panel and may be effectively dissipated in the peripheral region of the display panel, which may be beneficial for faster heat dissipation and improving the display quality. The sub-heat-dissipation portion may include the blade structure, and the main-heat-dissipation portion may be connected to the blade structure of the sub-heat-dissipation portion. The hollow region of the sub-heat-dissipation portion may be formed through the blade structure, thereby increasing the heat dissipation area of the sub-heat-dissipation portion. The heat may also be conducted through the hollow region around the blade structure by hollowing out of the sub-heat dissipation portion. That is, the hollow region may provide a heat conduction path, which may be beneficial for further accelerating the dissipation speed of heat conducted to the sub-heat-dissipation portion. Furthermore, the heat generated in the region of the display panel and conducted by the main-heat-dissipation portion may be more effectively dissipated through the sub-heat-dissipation portion, which may be beneficial for increasing overall heat dissipation speed of the display module, improving the display quality, and ensuring the service life of the module. The heat-dissipation part in the present disclosure may occupy less module space along the thickness direction of the module. Compared with the design structure in the existing technology that a cooling chassis or a cooling fan is installed behind the display panel, the configuration of the heat-dissipation part of the present disclosure may not only save cost and but also have simple structure. The space occupied, especially along the thickness direction of the module, may be relatively small, which may effectively avoid large-volume heat-dissipation part from affecting overall layout of the module, and may be beneficial for simplifying overall structure of the module.

Although some embodiments of the present disclosure have been described in detail through various embodiments, those skilled in the art should understand that above-mentioned embodiments may be for illustration only and may not be intended to limit the scope of the present disclosure. Those skilled in the art should understood that modifications may be made to above-mentioned embodiments without departing from the scope and spirit of the present disclosure. The scope of the present disclosure may be defined by the appended claims.

What is claimed is:

1. A display module, comprising:
a display panel and a heat-dissipation part, wherein:
the heat-dissipation part at least includes a main-heat-dissipation portion and a sub-heat-dissipation portion; and along a direction perpendicular to a plane of the display panel, the main-heat-dissipation portion is at least partially overlapped with the display panel;
along a direction in parallel with the plane of the display panel, the sub-heat-dissipation portion is at least on a side of the main-heat-dissipation portion; and
the sub-heat-dissipation portion includes a blade structure; and the main-heat-dissipation portion is connected to the blade structure of the sub-heat-dissipation portion.

2. The display module according to claim 1, wherein:
the main-heat-dissipation portion is disposed on a side of a backlight surface of the display panel.

3. The display module according to claim 1, wherein:
the main-heat-dissipation portion includes a hollow structure, and the blade structure includes a hollow structure; and
the hollow structure included in the blade structure and the hollow structure included in the main-heat-dissipation portion are connected to communicate with each other.

4. The display module according to claim 3, wherein:
a liquid or a gas is disposed in both the hollow structure included in the main-heat-dissipation portion and the hollow structure included in the blade structure.

5. The display module according to claim 3, wherein:
the hollow structure included in the main-heat-dissipation portion includes a support part, and/or the hollow structure included in the blade structure includes a support part; and the support part is fixedly connected to the heat-dissipation part.

6. The display module according to claim 1, wherein:
the display panel includes a first region and a second region;
the main-heat-dissipation portion includes a third region and a fourth region; along the direction perpendicular to the plane of the display panel, the display panel at the first region is overlapped with the main-heat-dissipation portion at the third region, and the display panel at the second region is overlapped with the main-heat-dissipation portion at the fourth region; and
a thermal conductivity of the main-heat-dissipation portion at the third region is greater than a thermal conductivity of the main-heat-dissipation portion at the fourth region.

7. The display module according to claim 6, wherein:
along the direction perpendicular to the plane of the display panel, a thickness of the main-heat-dissipation portion at the third region is greater than a thickness of the main-heat-dissipation portion at the fourth region.

8. The display module according to claim 6, wherein:
a material density of the main-heat-dissipation portion at the third region is greater than a material density of the main-heat-dissipation portion at the fourth region.

9. The display module according to claim 6, wherein:
a material of the main-heat-dissipation portion at the third region is different from a material of the main-heat-dissipation portion at the fourth region.

10. The display module according to claim 6, wherein:
the display panel further includes a transition region between the first region and the second region;
the main-heat-dissipation portion further includes a fifth region; and along the direction perpendicular to the plane of the display panel, the display panel at the transition region is overlapped with the main-heat-dissipation portion at the fifth region; and
a thermal conductivity of the main-heat-dissipation portion at the fifth region is greater than the thermal conductivity of the main-heat-dissipation portion at the fourth region; and the thermal conductivity of the main-heat-dissipation portion at the fifth region is less than the thermal conductivity of the main-heat-dissipation portion at the third region.

11. The display module according to claim 1, wherein:
the main-heat-dissipation portion is disposed on a side of a light-exiting surface of the display panel; and
the main-heat-dissipation portion includes a light-transmitting region; along the direction perpendicular to the plane of the display panel, the main-heat-dissipation portion at the light-transmitting region is overlapped with a display region of the display panel; and the main-heat-dissipation portion at the light-transmitting region is transparent.

12. The display module according to claim 1, wherein:
the blade structure is one of a flat block shape, a wavy shape and/or a cylindrical shape.

13. The display module according to claim 1, wherein:
the main-heat-dissipation portion includes a plurality of heat-conducting strips; and
the plurality of heat-conducting strips is inside the display panel and connected to the sub-heat dissipation portion.

14. The display module according to claim 13, wherein:
the display panel includes a plurality of light-emitting elements; and
an orthographic projection of the plurality of heat-conducting strips on the plane of the display panel is not overlapped with an orthographic projection of the plurality of light-emitting elements on the plane of the display panel.

15. The display module according to claim 13, wherein:
the display panel includes at least one insulating layer, and the plurality of heat-conducting strips is embedded in the insulating layer.

16. The display module according to claim 13, wherein:
the plurality of heat-conducting strips includes a first heat-conducting strip and a second heat-conducting strip in different film layers of the display panel.

17. The display module according to claim 13, wherein:
a heat-conducting strip of the plurality of heat-conducting strips includes a light-blocking material.

18. The display module according to claim 1, wherein:
the main-heat-dissipation portion and the display panel are fixed by a thermal conductive adhesive layer.

19. A vehicle terminal, comprising:
a display module, comprising:
a display panel and a heat-dissipation part, wherein:
the heat-dissipation part at least includes a main-heat-dissipation portion and a sub-heat-dissipation portion; and along a direction perpendicular to a plane of the display panel, the main-heat-dissipation portion is at least partially overlapped with the display panel;
along a direction in parallel with the plane of the display panel, the sub-heat-dissipation portion is at least on a side of the main-heat-dissipation portion; and
the sub-heat-dissipation portion includes a blade structure; and the main-heat-dissipation portion is connected to the blade structure of the sub-heat-dissipation portion.

20. The vehicle terminal according to claim 19, further including:
an air-conditioning outlet, wherein the sub-heat-dissipation portion is reused as the air-conditioning outlet.
